(19) United States
(12) Patent Application Publication
(10) Pub. No.: US 2026/0333976 A1
(43) Pub. Date: Oct. 22, 2026

(54) DISPLAY DEVICE

(71) Applicants: LG ELECTRONICS INC., Seoul (KR); LG DISPLAY CO., LTD., Seoul (KR)

(72) Inventors: Kyungdong LEE, Seoul (KR); Hongcheol LEE, Seoul (KR); Indo CHUNG, Seoul (KR); Sunyong SONG, Seoul (KR); Youngdo KIM, Seoul (KR)

(73) Assignees: LG ELECTRONICS INC., Seoul (KR); LG DISPLAY CO., LTD., Seoul (KR)

(21) Appl. No.: 19/121,376

(22) PCT Filed: Oct. 21, 2022
(86) PCT No.: PCT/KR2022/016191

§ 371 Date: Apr. 15, 2025

(51) Int. Cl. H10H 29/49; G09G 3/32; H10H 29/41

(52) U.S. Cl. CPC H10H 29/49; H10H 29/41; G09G 3/32; G09G 2300/0426; G09G 2300/0842

(57) ABSTRACT

The display device may include a first assembly wiring and a second assembly wiring on a substrate, a first insulating layer on the first assembly wiring and the second assembly wiring, a semiconductor light-emitting element comprising a passivation layer on the first insulating layer, a second insulating layer between the first insulating layer and the semiconductor light-emitting element, a connecting electrode on a lateral part of the semiconductor light-emitting element, a third insulating layer on the semiconductor light-emitting element, a fourth insulating layer on the third insulating layer, and an electrode wiring on the semiconductor light-emitting element. The connecting electrode may be connected to at least one of the first assembly wiring or the second assembly wiring through the first insulating layer. The electrode wiring may be connected to an upper side of the semiconductor light-emitting element through the fourth insulating layer, the third insulating layer, and the passivation layer of the semiconductor light-emitting element.

### TECHNICAL FIELD

The embodiment relates to a display device.

### BACKGROUND ART

A large-area display includes a liquid crystal display (LCD), an OLED display, and a micro-LED display.

A micro-LED display is a display that uses micro-LEDs, which are semiconductor light-emitting elements with a diameter or cross-sectional area of 100 μm or less, as display elements.

Since a micro-LED display uses micro-LEDs, which are semiconductor light-emitting elements, as display elements, it has excellent performance in many characteristics such as contrast ratio, response speed, color reproducibility, viewing angle, brightness, resolution, lifespan, luminous efficiency, or luminance.

In particular, a micro-LED display has the advantage of being able to freely adjust the size or resolution and implement a flexible display because the screen may be separated and combined in a modular manner.

However, since a large-area micro-LED display requires millions or more micro-LEDs, there is a technical problem that it is difficult to quickly and accurately transfer micro-LEDs to a display panel.

Recently developed transfer technologies include the pick and place process, the laser lift-off method, and the self-assembly method.

Among these, the self-assembly method is a method in which semiconductor light-emitting elements find their assembly positions in a fluid on their own, which is advantageous for implementing a large-screen display device.

However, research on the technology for manufacturing display through self-assembly of micro-LEDs is still insufficient.

In particular, in the conventional technology, when transferring millions or more semiconductor light-emitting elements to a large display quickly, the transfer speed can be improved, but the transfer error rate may increase, which causes a technical problem in that the transfer yield is low.

In the related technology, a self-assembly transfer process using dielectrophoresis (DEP) is being attempted, but there is a problem in that the self-assembly rate is low due to the unevenness of the DEP force.

Meanwhile, as illustrated in FIGS. 1 and 2, an assembly hole 7 is formed on a substrate 1 for self-assembly, and a semiconductor light-emitting element 8 is assembled into the assembly hole 7. Thereafter, a metal film 9 is deposited on the substrate 1 using a deposition process to form a lateral electrode.

However, since the gap between the outer surface of the semiconductor light-emitting element 8 and the inner surface of the assembly hole 7 is very narrow, it is difficult for the metal material to be transferred to the first assembly wiring 2 and the second assembly wiring 3 through this gap, and even if the metal material is transferred to the first assembly wiring 2 and the second assembly wiring 3, there is a limit to depositing a thick film thickness, so that there is a problem that an electrical disconnection occurs or the film quality deteriorates. This problem is likely to be carried over to a post-process, and there is a problem that it causes a lighting defect when implementing a display device.

The unexplained drawing numeral 6 is a partition wall, which is provided to form the assembly hole 7. The unexplained drawing numeral 4 is an insulating layer, which protects the first assembly wiring 2 and the second assembly wiring 3.

According to the non-public internal technology, as illustrated in FIG. 2, after the semiconductor light-emitting element 8 is assembled in the assembly hole 7, the metal film 9 is not formed, but the partition wall 6 may be removed. Since the partition wall 6 is removed, there is no physical obstruction in the lateral direction of the semiconductor light-emitting element 8. Accordingly, the metal film 9 is deposited on the substrate 1 as well as the semiconductor light-emitting element 8 without any physical obstruction in the lateral direction of the semiconductor light-emitting element 8, and this metal film 9 is patterned so that the lateral part of the semiconductor light-emitting element 8 and the first assembly wiring 2 may be electrically connected.

However, when the partition wall 6 is removed using an ashing process, as illustrated in FIG. 3(a), an oxidized organic residual film 11 is formed on the substrate 1 corresponding to a region where the partition wall 6 was. That is, the partition wall 6 is removed by dry etching using O₂ plasma as an ashing process. In this instance, the partition wall 6 is oxidized by oxygen (O₂) and the oxidized organic residue film 11 is formed on a surface of the substrate 1.

As illustrated in FIG. 3(b), when a metal film is deposited and patterned to form a lateral electrode 12 while the oxidized organic residue film 11 is formed, there is a problem that the lateral electrode 12 is disconnected or the roughness of the lateral electrode 12 increases due to the oxidized organic residue film 11, resulting in an increase in electrical resistance.

In addition, since the thickness of the partition wall 6 is thick, it takes a long time to completely remove the partition wall 6 by the ashing process, which increases the process time.

Meanwhile, as illustrated in FIGS. 1 and 2, since a process of fixing the semiconductor light-emitting element 8 to the insulating layer 4 must be added so that the semiconductor light-emitting element 8 does not fall out of the assembly hole 7 while the metal film 9 is formed after the semiconductor light-emitting element 8 is assembled or the metal film 9 is formed after the partition wall 6 is removed, there is a problem that the process time becomes long and complicated.

### DISCLOSURE

### Technical Problem

An object of the embodiment is to solve the foregoing and other problems.

Another object of the embodiment is to provide a display device with easy electrical connection.

In addition, another object of the embodiment is to provide a display device capable of enhancing the fixation of the semiconductor light-emitting element.

In addition, another object of the embodiment is to provide a display device capable of enhancing the fixation of the electrode wiring.

In addition, another object of the embodiment is to provide a display device in which the formation of the second insulating layer and the third insulating layer and the removal of the partition wall are performed simultaneously, so that the process is simple and the process time can be drastically shortened.

The technical problems of the embodiments are not limited to those described in this item and include those that may be understood through the description of the invention.

### Technical Solution

According to one aspect of the embodiment, in order to achieve the above or other objects, A display device comprises: a substrate comprising a plurality of pixels, each comprising a plurality of subpixels; a first assembly wiring and a second assembly wiring for each of the plurality of subpixels; a first insulating layer on the first assembly wiring and the second assembly wiring; a semiconductor light-emitting element comprising a passivation layer on each of the plurality of subpixels; a second insulating layer between the first insulating layer and the semiconductor light-emitting element; a connecting electrode on a lateral part of the semiconductor light-emitting element; a third insulating layer on the semiconductor light-emitting element; a fourth insulating layer on the third insulating layer; and an electrode wiring on the semiconductor light-emitting element, wherein the connecting electrode is configured to be connected to at least one of the first assembly wiring or the second assembly wiring through the first insulating layer, and wherein the electrode wiring is configured to be connected to the upper side of the semiconductor light-emitting element through the fourth insulating layer, the third insulating layer, and the passivation layer of the semiconductor light-emitting element.

The second insulating layer may be a fixed layer.

The third insulating layer may be a fixed layer.

The third insulating layer may surround the electrode wiring.

The second insulating layer and the third insulating layer may comprise a same material. The second insulating layer and the third insulating layer may comprise a photosensitive material.

The semiconductor light-emitting element may comprise a light-emitting layer; the passivation layer surrounding the light-emitting layer; and an electrode below the light-emitting layer.

The third insulating layer may comprise a third-first insulating layer on the upper side of the semiconductor light-emitting element; and a third-second insulating layer extending from the third-first insulating layer and surrounding the lateral part of the semiconductor light-emitting element.

The electrode of the semiconductor light-emitting element may be in contact with the third-second insulating layer and the connecting electrode.

The third insulating layer may comprise a third-first insulating pattern on a part of an upper region of the semiconductor light-emitting element; and a third-second insulating pattern extending from the third-first insulating pattern and on a part of a lateral part of the semiconductor light-emitting element.

The third-second insulating pattern may be connected to the second insulating layer.

The electrode may be in contact with the third-second insulating pattern and the connecting electrode.

The connecting electrode may comprise a first connecting electrode on a lateral part of the semiconductor light-emitting element; a second connecting electrode on at least one of the first assembly wiring or the second assembly wiring; and a third connecting electrode on the first insulating layer.

The light-emitting layer may comprise a first region and a second region surrounding the first region, and the connecting electrode may comprise a fourth connecting electrode below the second region of the light-emitting layer.

The second insulating layer may be disposed below the first region of the light-emitting layer.

The fourth connecting electrode may surround the second insulating layer.

The semiconductor light-emitting element may have a size of 5 micrometers or less.

### Advantageous Effects

As illustrated in FIGS. 10 to 27, the semiconductor light-emitting element 150-1 can be firmly fixed to the first insulating layer 330 by the second insulating layer 335, thereby enhancing the fixation of the semiconductor light-emitting element 150-1.

As illustrated in FIGS. 10 to 27, since the third insulating layer 345 surrounds the lateral part of the electrode wiring 360, the electrode wiring 360 can be firmly fixed to the upper side of the semiconductor light-emitting element 150-1 by the third insulating layer 345. Accordingly, the peeling problem of the electrode wiring 360 can be solved. In particular, when the fourth insulating layer 350 is not disposed on the semiconductor light-emitting element 150-1 in order to reduce the thickness of the fourth insulating layer 350, the electrode wiring 360 can be firmly fixed to the upper side of the semiconductor light-emitting element 150-1 by the third insulating layer 345. Accordingly, the overall thickness of the display devices 301 to 305 according to the embodiment can be reduced, and the peeling problem of the electrode wiring 360 can also be solved. The third insulating layer 345 may be made of a photosensitive material, so that the fixing property for the electrode wiring 360 can be further strengthened.

As illustrated in FIGS. 16 to 19B, the second insulating layer 335 and the third insulating layer 345 may be formed simultaneously. In addition, the formation of the second insulating layer 335 and the third insulating layer 345 and the removal of the partition wall 340 may be performed simultaneously. Accordingly, the process can be very simple and the process time can be dramatically shortened. In addition, since the partition wall 340 is made of a photosensitive material, not only can the partition wall 340, which has been exposed to light by the exposure process, be easily removed, but also no trace of the partition wall 340 can remain, so that the surface of the first insulating layer 330 below the partition wall 340 is clean. Thus, the connecting electrode 370 may be formed with a constant thickness without disconnection, and the upper surface of the layer disposed on the first insulating layer 330 may also be formed to have a straight plane.

As illustrated in FIGS. 28 to 37, the third insulating layer 345 may be disposed not only on the upper side of the semiconductor light-emitting element 150-1 but also on the lateral part of the semiconductor light-emitting element 150-1, so that the third insulating layer 345 may fix the electrode wiring 360 to the semiconductor light-emitting element 150-1 and at the same time fix the semiconductor light-emitting element 150-1 to the first insulating layer 330 through the second insulating layer 335. In particular, by connecting the second insulating layer 335 and the third insulating layer 345, the semiconductor light-emitting element 150-1 can be more firmly fixed to the first insulating layer 330 by the second insulating layer 335 and the third insulating layer 345.

As illustrated in FIG. 38 and FIG. 39, by making the size (or diameter) of the second insulating layer 335 smaller than the size (or diameter) of the semiconductor light-emitting element 150-1, a part of the connecting electrode 370, that is, the fourth connecting electrode 370-4, may be disposed below a second region 150b surrounding a first region 150a of the semiconductor light-emitting element 150-1. Accordingly, by being in contact with the semiconductor light-emitting element 150-1 with the first connecting electrode 370-1 as well as the fourth connecting electrode 370-4 of the connecting electrode 370 disposed on the lateral part of the semiconductor light-emitting element 150-1, the contact area for the semiconductor light-emitting element 150-1 can be maximized, so that the electrical characteristics can be improved. Accordingly, the operating voltage can be lowered or the light efficiency and light luminance can be improved.

As illustrated in FIG. 40, a recess 330a of the first insulating layer 330 may be formed between the first assembly wiring 321 and the second assembly wiring 322, and the second insulating layer 335 may be disposed not only on the upper surface of the first insulating layer 330 but also in the recess 330a, so that the contact area between the second insulating layer 335 and the first insulating layer 330 can be expanded, so that the semiconductor light-emitting element 150-1 can be more firmly fixed to the first insulating layer 330.

Additional scope of applicability of the embodiments will become apparent from the detailed description that follows. However, since various changes and modifications within the idea and scope of the embodiments may be clearly understood by those skilled in the art, the detailed description and specific embodiments, such as preferred embodiments, should be understood as being given by way of example only.

### DESCRIPTION OF DRAWINGS

FIG. 1 is a plan view illustrating a semiconductor light-emitting element assembled in an assembly hole using an assembly method.

FIG. 2 is a cross-sectional view illustrating a disconnection occurring during metal deposition.

FIG. 3(a) is a plan view showing an oxidized organic residue film occurring when a partition wall is removed.

FIG. 3(b) is a cross-sectional view showing a defect in a lateral electrode caused by the oxidized organic residue film of FIG. 3(a).

FIG. 4 illustrates a living room of a house in which a display device according to the embodiment is disposed.

FIG. 5 is a block diagram schematically showing a display device according to an embodiment.

FIG. 6 is a circuit diagram showing an example of a pixel of FIG. 5.

FIG. 7 is an enlarged view of a first panel region in the display device of FIG. 4.

FIG. 8 is an enlarged view of a region A2 area of FIG. 7.

FIG. 9 is a drawing illustrating an example of assembling a light-emitting element according to an embodiment on a substrate by a self-assembly method.

FIG. 10 is a plan view illustrating a display device according to a first embodiment.

FIG. 11 is a cross-sectional view taken along the C1-C2 line of FIG. 10.

FIGS. 12 to 26 illustrate a manufacturing process of a display device according to the first embodiment.

FIG. 27 shows an upper surface of the first insulating layer exposed by a removal of the partition wall and the photosensitive film in FIG. 18.

FIG. 28 is a plan view illustrating a display device according to a second embodiment.

FIG. 29 is a cross-sectional view of a display device according to the second embodiment of FIG. 28 taken along the line D1-D2.

FIG. 30 is a cross-sectional view of a display device according to the second embodiment of FIG. 28 taken along the line E1-E2.

FIGS. 31 to 34 illustrate a manufacturing process of a display device according to the second embodiment.

FIG. 35 is a plan view illustrating a display device according to a third embodiment.

FIG. 36 is a cross-sectional view of a display device according to the third embodiment of FIG. 35 taken along the line F1-F2.

FIG. 37 is a cross-sectional view of a display device according to the third embodiment of FIG. 35 taken along the line G1-G2.

FIG. 38 is a cross-sectional view illustrating a display device according to a fourth embodiment.

FIG. 39 illustrates the arrangement relationship between a semiconductor light-emitting element, a second insulating layer, and a fourth connecting electrode.

FIG. 40 is a cross-sectional view illustrating a display device according to a fifth embodiment.

The sizes, shapes, dimensions, etc. of elements illustrated in the drawings may differ from actual ones. In addition, even if the same elements are illustrated in different sizes, shapes, dimensions, etc. between the drawings, this is only an example on the drawing, and the same elements have the same sizes, shapes, dimensions, etc. between the drawings.

### MODE FOR INVENTION

Hereinafter, the embodiment disclosed in this specification will be described in detail with reference to the accompanying drawings, but the same or similar elements are given the same reference numerals regardless of reference numerals, and redundant descriptions thereof will be omitted. The suffixes ‘module’ and ‘unit’ for the elements used in the following descriptions are given or used interchangeably in consideration of ease of writing the specification, and do not themselves have a meaning or role that is distinct from each other. In addition, the accompanying drawings are for easy understanding of the embodiment disclosed in this specification, and the technical idea disclosed in this specification is not limited by the accompanying drawings. Also, when an element such as a layer, region or substrate is referred to as being ‘on’ another element, this means that there may be directly on the other element or be other intermediate elements therebetween.

The display device described in this specification may comprise a TV, signage, a mobile terminal such as a mobile phone or a smart phone, display for computer such as a laptop or a desktop, a head-up display (HUD) for an automobile, a backlight unit for display, display for VR, AR or mixed reality (MR), a light source, etc. However, the configuration according to the embodiment described in this specification may be equally applied to a device capable of displaying, even if it is a new product type developed in the future.

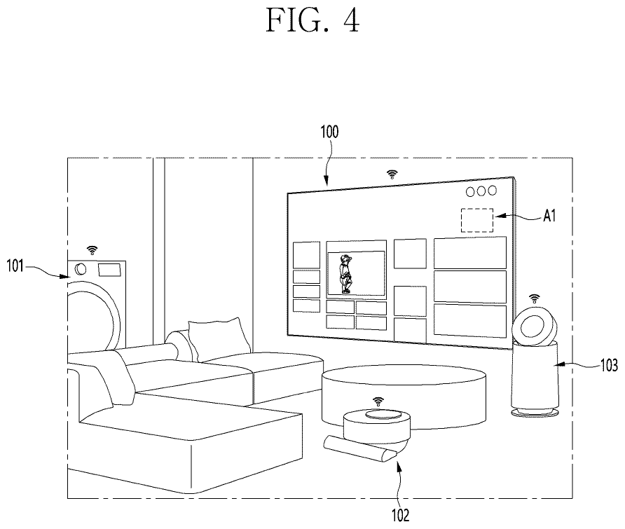

FIG. 4 illustrates a living room of a house in which a display device according to the embodiment is disposed.

Referring to FIG. 4, the display device 100 according to the embodiment may display the status of various electronic products such as a washing machine 101, a robot vacuum cleaner 102, an air purifier 103, etc., may communicate with each electronic product based on IoT, and may control each electronic product based on user setting data.

The display device 100 according to the embodiment may comprise a flexible display manufactured on a thin and flexible substrate. The flexible display may maintain the characteristics of an existing flat panel display, but may be bent or rolled like paper.

In a flexible display, visual information may be implemented by independently controlling the light emission of unit pixels disposed in a matrix form. A unit pixel means a minimum unit for implementing one color. A unit pixel of a flexible display may be implemented by a light-emitting element. In an embodiment, the light-emitting element may be a micro-LED or a nano-LED, but is not limited thereto.

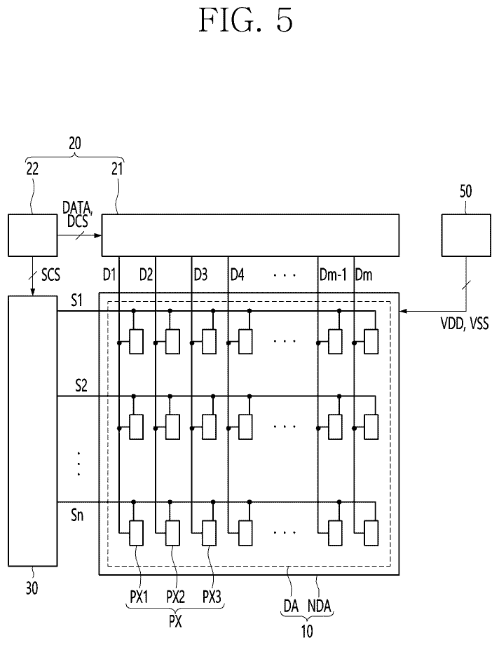

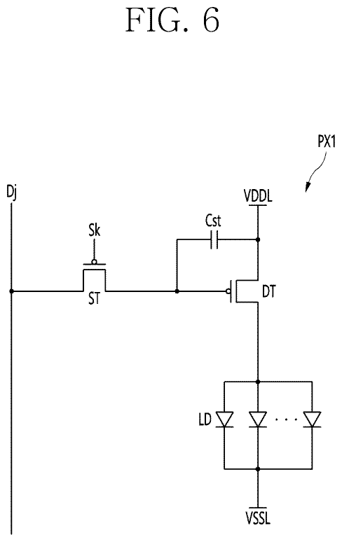

FIG. 5 is a block diagram schematically showing a display device according to an embodiment, and FIG. 6 is a circuit diagram showing an example of a pixel of FIG. 5.

Referring to FIG. 5 and FIG. 6, a display device according to an embodiment may comprise a display panel 10, a driving circuit 20, a scan driving unit 30, and a power supply circuit 50.

The display device 100 of the embodiment may drive a light-emitting element in an active matrix (AM) manner or a passive matrix (PM) manner.

The driving circuit 20 may comprise a data driving unit 21 and a timing control unit 22.

The display panel 10 may be formed in a rectangular shape, but is not limited thereto. That is, the display panel 10 may be formed in a circular or oval shape. At least one side of the display panel 10 may be formed to be bent at a predetermined curvature.

The display panel may comprise a display region DA. The display region DA is a region where pixels PX are formed to display an image. The display panel may comprise a non-display region NDA. The non-display region NDA may be a region excluding the display region DA.

As an example, the display region DA and the non-display region NDA may be defined on the same surface. For example, the non-display region NDA may surround the display region DA on the same surface as the display region DA, but is not limited thereto.

As another example, although not illustrated in the drawing, the display region DA and the non-display region NDA may be defined on different surfaces. For example, the display region DA may be defined on the upper surface of the substrate, and the non-display region NDA may be defined on the lower surface of the substrate. For example, the non-display region NDA may be defined on the entire region or a part of the lower surface of the substrate.

Meanwhile, although the drawing illustrates that the display region DA and the non-display region NDA are divided, the display region DA and the non-display region NDA may not be divided. In other words, only the display region DA may exist on the upper surface of the substrate, and the non-display region NDA may not exist. In other words, the entire region of the upper surface of the substrate may be the display region DA where the image is displayed, and a bezel region, which is the non-display region NDA, may not exist.

The display panel 10 may comprise data lines (DI to Dm, where m is an integer greater than or equal to 2), scan lines (S1 to Sn, where n is an integer greater than or equal to 2) intersecting the data lines D1 to Dm, a high-potential voltage line VDDL supplied with a high-potential voltage VDD, a low-potential voltage line VSSL supplied with a low-potential voltage VSS, and pixels PX connected to the data lines D1 to Dm and the scan lines S1 to Sn. Each of the pixels PX may comprise a first subpixel PX1, a second subpixel PX2, and a third subpixel PX3. The first subpixel PX1 may emit a first color light of a first main wavelength, the second subpixel PX2 may emit a second color light of a second main wavelength, and the third subpixel PX3 may emit a third color light of a third main wavelength. The first color light may be red light, the second color light may be green light, and the third color light may be blue light, but the present invention is not limited thereto. In addition, although FIG. 5 exemplifies that each of the pixels PX comprises three subpixels, the present invention is not limited thereto. That is, each of the pixels PX may comprise four or more subpixels.

Each of the first subpixel PX1, the second subpixel PX2, and the third subpixel PX3 may be connected to at least one of the data lines DI to Dm, at least one of the scan lines S1 to Sn, and a high-potential voltage line VDDL. The first subpixel PX1 may comprise light-emitting elements LD, a plurality of transistors for supplying current to the light-emitting elements LD, and at least one capacitor Cst, as illustrated in FIG. 6.

Although not illustrated in the drawing, each of the first subpixel PX1, the second subpixel PX2, and the third subpixel PX3 may comprise only one light-emitting element LD and at least one capacitor Cst.

Each of the light-emitting elements LD may be a semiconductor light-emitting diode comprising a first electrode, a plurality of conductivity type semiconductor layers, and a second electrode. Here, the first electrode may be an anode electrode, and the second electrode may be a cathode electrode, but is not limited thereto.

The light-emitting element LD may be one of a lateral-type light-emitting element, a flip-chip type light-emitting element, and a vertical-type light-emitting element.

The plurality of transistors may comprise a driving transistor DT for supplying current to the light-emitting elements LD, and a scan transistor ST for supplying a data voltage to a gate electrode of the driving transistor DT, as illustrated in FIG. 6. The driving transistor DT may comprise a gate electrode connected to a source electrode of the scan transistor ST, a source electrode connected to a high-potential voltage line VDDL to which a high-potential voltage VDD is applied, and a drain electrode connected to a first electrodes of the light-emitting elements LD. The scan transistor ST may comprise a gate electrode connected to a scan line (Sk, where k is an integer satisfying 1≤k≤n), a source electrode connected to a gate electrode of a driving transistor DT, and a drain electrode connected to a data line (Dj, where j is an integer satisfying 1≤j≤m).

A capacitor Cst is formed between the gate electrode and the source electrode of the driving transistor DT. The storage capacitor Cst charges the difference between the gate voltage and the source voltage of the driving transistor DT.

The driving transistor DT and the scan transistor ST may be formed as thin film transistors. In addition, although FIG. 6 mainly describes the driving transistor DT and the scan transistor ST formed as P-type metal oxide semiconductor field effect transistors (MOSFETs), the present invention is not limited thereto. The driving transistor DT and the scan transistor ST may also be formed as N-type MOSFETs. In this instance, the positions of the source electrode and the drain electrode of each of the driving transistor DT and the scan transistors ST may be changed.

In addition, in FIG. 6, the first subpixel PX1, the second subpixel PX2, and the third subpixel PX3 each comprise 2T1C (2 Transistor-1 capacitor) having one driving transistor DT, one scan transistor ST, and one capacitor Cst, but the present invention is not limited thereto. The first subpixel PX1, the second subpixel PX2, and the third subpixel PX3 each may comprise a plurality of scan transistors ST and a plurality of capacitors Cst.

Since the second subpixel PX2 and the third subpixel PX3 may be expressed in substantially the same circuit diagram as the first subpixel PX1, a detailed description thereof will be omitted.

The driving circuit 20 outputs signals and voltages for driving the display panel 10. To this end, the driving circuit 20 may comprise a data driving unit 21 and a timing control unit 22.

The data driving unit 21 receives digital video data DATA and a source control signal DCS from the timing control unit 22. The data driving unit 21 converts the digital video data DATA into analog data voltages according to the source control signal DCS and supplies the converted data to the data lines D1 to Dm of the display panel 10.

The timing control unit 22 receives digital video data DATA and timing signals from the host system. The host system may be an application processor of a smartphone or tablet PC, a monitor, a system on chip of a TV, etc.

The timing control unit 22 generates control signals for controlling the operation timing of the data driving unit 21 and the scan driving unit 30. The control signals may comprise a source control signal DCS for controlling the operation timing of the data driving unit 21 and a scan control signal SCS for controlling the operation timing of the scan driving unit 30.

The driving circuit 20 may be disposed in a non-display region NDA provided on one side of the display panel 10. The driving circuit 20 may be formed as an integrated circuit (IC) and mounted on the display panel 10 in a chip on glass (COG) manner, a chip on plastic (COP) manner, or an ultrasonic bonding manner, but the present invention is not limited thereto. For example, the driving circuit 20 may be mounted on a circuit board (not illustrated) other than the display panel 10.

The data driving unit 21 may be mounted on the display panel 10 in a chip on glass (COG) manner, a chip on plastic (COP) manner, or an ultrasonic bonding manner, and the timing control unit 22 may be mounted on the circuit board.

The scan driving unit 30 receives a scan control signal SCS from the timing control unit 22. The scan driving unit 30 generates scan signals according to the scan control signal SCS and supplies them to scan lines S1 to Sn of the display panel 10. The scan driving unit 30 may be formed in the non-display region NDA of the display panel 10 and comprise a plurality of transistors. Alternatively, the scan driving unit 30 may be formed as an integrated circuit, in which case it may be mounted on a gate flexible film attached to another side of the display panel 10.

The power supply circuit 50 may generate voltages required for driving the display panel 10 from the main power applied from the system board and supply them to the display panel 10. For example, the power supply circuit 50 may generate a high-potential voltage VDD and a low-potential voltage VSS for driving the light-emitting elements LD of the display panel 10 from the main power and supply them to the high-potential voltage line VDDL and the low-potential voltage line VSSL of the display panel 10. In addition, the power supply circuit 50 may generate and supply driving voltages for driving the driving circuit 20 and the scan driving unit 30 from the main power.

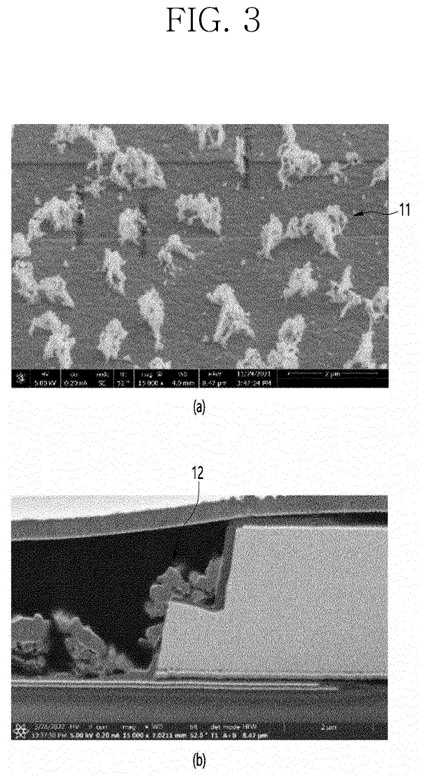

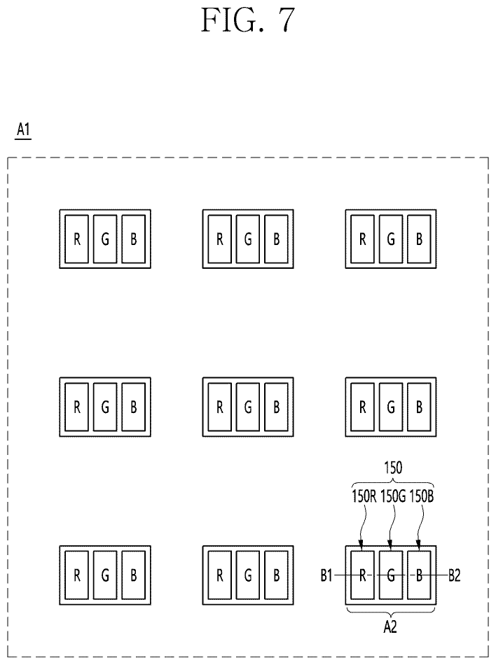

FIG. 7 is an enlarged view of the first panel region in the display device of FIG. 3.

Referring to FIG. 7, the display device 100 of the embodiment may be manufactured by mechanically and electrically connecting a plurality of panel areas such as the first panel region Al by tiling.

The first panel region Al may comprise a plurality of semiconductor light-emitting elements 150 disposed for each unit pixel (PX of FIG. 5).

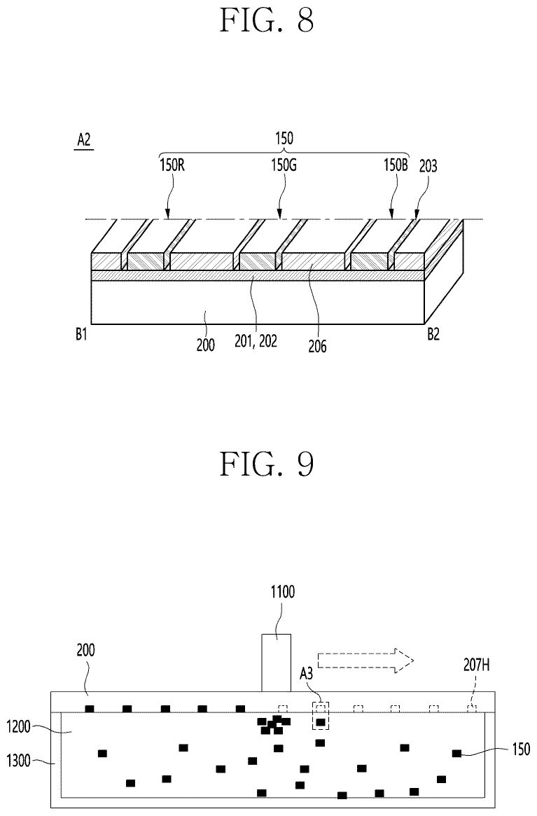

FIG. 8 is an enlarged view of a region A2 area of FIG. 7.

Referring to FIG. 8, the display device 100 of the embodiment may comprise a substrate 200, assembly wirings 201 and 202, an insulating layer 206, and a plurality of semiconductor light-emitting elements 150. More components may be included than these.

The assembly wirings may comprise a first assembly wiring 201 and a second assembly wiring 202 that are spaced apart from each other. The first assembly wiring 201 and the second assembly wiring 202 may be provided to generate a dielectrophoretic force (DEP force) to assemble the semiconductor light-emitting element 150. For example, the semiconductor light-emitting element 150 may be one of a lateral-type semiconductor light-emitting element, a flip-chip type semiconductor light-emitting element, and a vertical-type semiconductor light-emitting element.

The semiconductor light-emitting element 150 may comprise a red semiconductor light-emitting element 150R, a green semiconductor light-emitting element 150G, and a blue semiconductor light-emitting element 150B to form a unit pixel, but is not limited thereto, and a red phosphor and a green phosphor are provided to implement red and green, respectively.

The substrate 200 may be a support member that supports components disposed on the substrate 200 or a protective member that protects the components.

The substrate 200 may be a rigid substrate or a flexible substrate. The substrate 200 may be formed of sapphire, glass, silicon, or polyimide. In addition, the substrate 200 may comprise a flexible material such as polyethylene naphthalate (PEN), polyethylene terephthalate (PET). In addition, the substrate 200 may be a transparent material, but is not limited thereto. The substrate 200 may function as a support substrate in a display panel, and may also function as an assembly substrate when self-assembling a light-emitting element.

The substrate 200 may be a backplane equipped with circuits, such as transistors ST and DT, capacitors Cst, signal wiring, etc., within the subpixels PX1, PX2, and PX3 illustrated in FIGS. 5 and 6, but is not limited thereto.

The insulating layer 206 may comprise an organic material having insulation and flexibility, such as polyimide, PAC, PEN, PET, polymer, or an inorganic material such as silicon oxide (SiO₂) or silicon nitride series (SiNx), and may be formed integrally with the substrate 200 to form a single substrate.

The insulating layer 206 may be a conductive adhesive layer having adhesion and conductivity, and the conductive adhesive layer may have flexibility to enable a flexible function of the display device. For example, the insulating layer 206 may be a conductive adhesive layer such as an anisotropic conductive film (ACF) or an anisotropic conductive medium, a solution containing conductive particles, etc. The conductive adhesive layer may be a layer that is electrically conductive in a direction vertical to the thickness, or electrically insulating in a direction horizontal to the thickness.

The insulating layer 206 may comprise an assembly hole 203 for inserting a semiconductor light-emitting element 150. Therefore, when self-assembling, the semiconductor light-emitting element 150 may be easily inserted into the assembly hole 203 of the insulating layer 206. The assembly hole 203 may be called an insertion hole, a fixing hole, an alignment hole, etc. The assembly hole 203 may also be called a hole.

The assembly hole 203 may be called a hole, a groove, a recess, a pocket, etc.

The assembly hole 203 may be different depending on the shape of the semiconductor light-emitting element 150. For example, the red semiconductor light-emitting element, the green semiconductor light-emitting element, and the blue semiconductor light-emitting element each have different shapes, and assembly holes 203 having shapes corresponding to shapes of these semiconductor light-emitting elements may be provided. For example, the assembly holes 203 may comprise a first assembly hole for assembling the red semiconductor light-emitting element, a second assembly hole for assembling the green semiconductor light-emitting element, and a third assembly hole for assembling the blue semiconductor light-emitting element. For example, the red semiconductor light-emitting element may have a circular shape, the green semiconductor light-emitting element may have a first oval shape having a first minor axis and a first major axis, and the blue semiconductor light-emitting element may have a second oval shape having a second minor axis and a second major axis, but is not limited thereto. The second major axis of the oval shape of the blue semiconductor light-emitting element may be larger than the first major axis of the oval shape of the green semiconductor light-emitting element, and the second minor axis of the oval shape of the blue semiconductor light-emitting element may be smaller than the first minor axis of the oval shape of the green semiconductor light-emitting element.

Meanwhile, the method of mounting the semiconductor light-emitting element 150 on the substrate 200 may comprise, for example, a self-assembly method (FIG. 9) and a transfer method.

FIG. 9 is a drawing illustrating an example in which a light-emitting element according to an embodiment is assembled on a substrate by a self-assembly method.

Based on FIG. 9, an example in which a semiconductor light-emitting element according to an embodiment is assembled on a display panel by a self-assembly method using an electromagnetic field will be described.

The assembly substrate 200 described below may also function as a panel substrate in a display device after assembling the light-emitting element, but the embodiment is not limited thereto.

Referring to FIG. 9, the semiconductor light-emitting element 150 may be put into in a chamber 1300 filled with a fluid 1200, and the semiconductor light-emitting element 150 may be moved to the assembly substrate 200 by a magnetic field generated from the assembly device 1100. At this time, the semiconductor light-emitting element 150 adjacent to the assembly hole 207H of the assembly substrate 200 may be assembled into the assembly hole 207H by the DEP force caused by the electric field of the assembly wirings. The fluid 1200 may be water such as ultrapure water, but is not limited thereto. The chamber may be called a tank, a container, a vessel, etc.

After the semiconductor light-emitting element 150 is put into in the chamber 1300, the assembly substrate 200 may be disposed on the chamber 1300. According to an embodiment, the assembly substrate 200 may be put into the chamber 1300.

The semiconductor light-emitting element 150 may be implemented as a vertical-type semiconductor light-emitting element as illustrated, but is not limited thereto, and a lateral-type light-emitting element may be employed.

The semiconductor light-emitting element 150 may comprise a magnetic layer (not illustrated) having a magnetic substance. The magnetic layer may comprise a metal having magnetism, such as nickel (Ni). Since the semiconductor light-emitting element 150 put into the fluid comprises the magnetic layer, it may move to the assembly substrate 200 by a magnetic field generated from the assembly device 1100. The magnetic layer may be disposed on the upper side or lower side or both sides of the light-emitting element.

Meanwhile, the first assembly wiring 201 and the second assembly wiring 202 form an electric field as an AC voltage is applied, and the semiconductor light-emitting element 150 inserted into the assembly hole 207H may be fixed by the DEP force due to the electric field. The gap between the first assembly wiring 201 and the second assembly wiring 202 may be smaller than the width of the semiconductor light-emitting element 150 and the width of the assembly hole 207H, and the assembly position of the semiconductor light-emitting element 150 may be fixed more precisely using the electric field.

An insulating layer 215 is formed on the first assembly wiring 201 and the second assembly wiring 202 to protect the first assembly wiring 201 and the second assembly wiring 202 from the fluid 1200 and prevent leakage of current flowing in the first assembly wiring 201 and the second assembly wiring 202. For example, the insulating layer 215 may be formed of a single layer or multiple layers of an inorganic insulator such as silica or alumina, or an organic insulator. The insulating layer 215 may have a minimum thickness to prevent damage to the first assembly wiring 201 and the second assembly wiring 202 during assembly of the semiconductor light-emitting element 150, and may have a maximum thickness to stably assemble the semiconductor light-emitting element 150.

A partition wall 207 may be formed on the upper part of the insulating layer 215. A part of the partition wall 207 may be positioned on the upper part of the first assembly wiring 201 and the second assembly wiring 202, and the remaining areas may be positioned on the upper part of the assembly substrate 200.

Meanwhile, when manufacturing the assembly substrate 200, a part of the partition wall formed on the upper part of the insulating layer 215 may be removed, thereby forming an assembly hole 207H in which each of the semiconductor light-emitting elements 150 is coupled and assembled to the assembly substrate 200.

An assembly hole 207H is formed in the assembly substrate 200, into which semiconductor light-emitting elements 150 are combined, and a surface on which the assembly hole 207H is formed may be in contact with a fluid 1200. The assembly hole 207H may guide an accurate assembly position of the semiconductor light-emitting element 150.

Meanwhile, the assembly hole 207H may have a shape and size corresponding to the shape of the semiconductor light-emitting element 150 to be assembled at a corresponding position. Accordingly, it is possible to prevent another semiconductor light-emitting element from being assembled in the assembly hole 207H or a plurality of semiconductor light-emitting elements from being assembled in the assembly hole 207H. can be prevented

Referring again to FIG. 9, after the assembly substrate 200 is disposed in the chamber, an assembly device 1100 that applies a magnetic field may move along the assembly substrate 200. The assembly device 1100 may be a permanent magnet or an electromagnet.

The assembly device 1100 may move in contact with the assembly substrate 200 to maximize a region affected by the magnetic field within the fluid 1200. Depending on the embodiment, the assembly device 1100 may comprise a plurality of magnetic substances or may comprise a magnetic substance of a size corresponding to the assembly substrate 200. In this instance, the movement distance of the assembly device 1100 may be limited within a predetermined range.

The semiconductor light-emitting element 150 within the chamber 1300 may move toward the assembly device 1100 and the assembly substrate 200 by the magnetic field generated by the assembly device 1100.

The semiconductor light-emitting element 150 may enter the assembly hole 207H and be fixed by the DEP force formed by the electric field between the assembly wirings 201 and 202 while moving toward the assembly device 1100.

Specifically, the first and second assembly wirings 201 and 202 form an electric field by an AC power source, and a DEP force may be formed between the assembly wirings 201 and 202 by this electric field. The semiconductor light-emitting element 150 may be fixed to the assembly hole 207H on the assembly substrate 200 by this DEP force.

At this time, a predetermined solder layer (not illustrated) is formed between the semiconductor light-emitting element 150 assembled on the assembly hole 207H of the assembly substrate 200 and the assembly wirings 201 and 202, thereby improving the binding force of the semiconductor light-emitting element 150.

In addition, a molding layer (not illustrated) may be formed on the assembly hole 207H of the assembly substrate 200 after assembly. The molding layer may be a transparent resin or a resin containing a reflective material or a scattering material.

Since the time required for each semiconductor light-emitting element to be assembled on a substrate can be drastically shortened by the self-assembly method using the electromagnetic field described above, a large-area, high-pixel display may be implemented more quickly and economically.

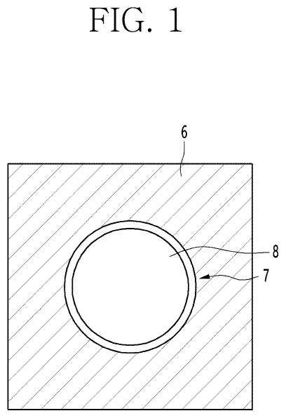

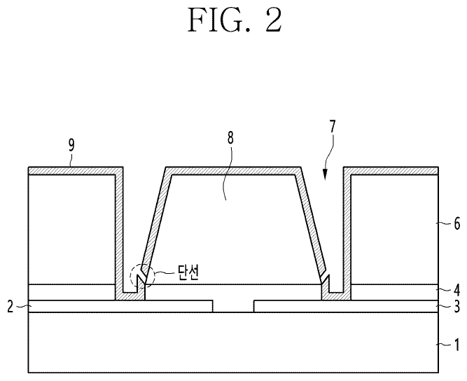

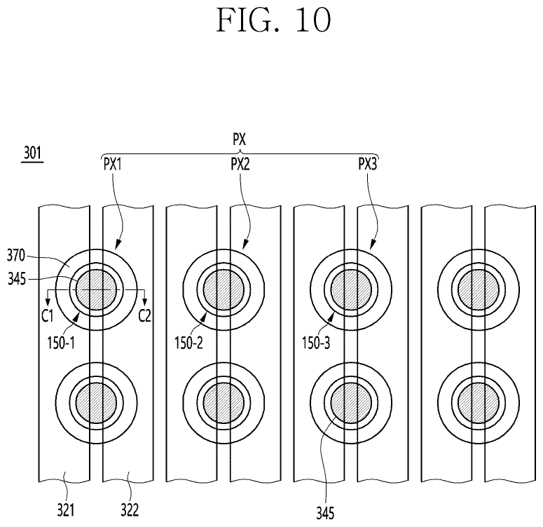

Hereinafter, various embodiments for solving the above-described problem will be described with reference to FIGS. 10 to 40. Any explanation omitted below may be easily understood from the explanations given above in connection with FIGS. 1 to 9 and the corresponding drawings.

### First Embodiment

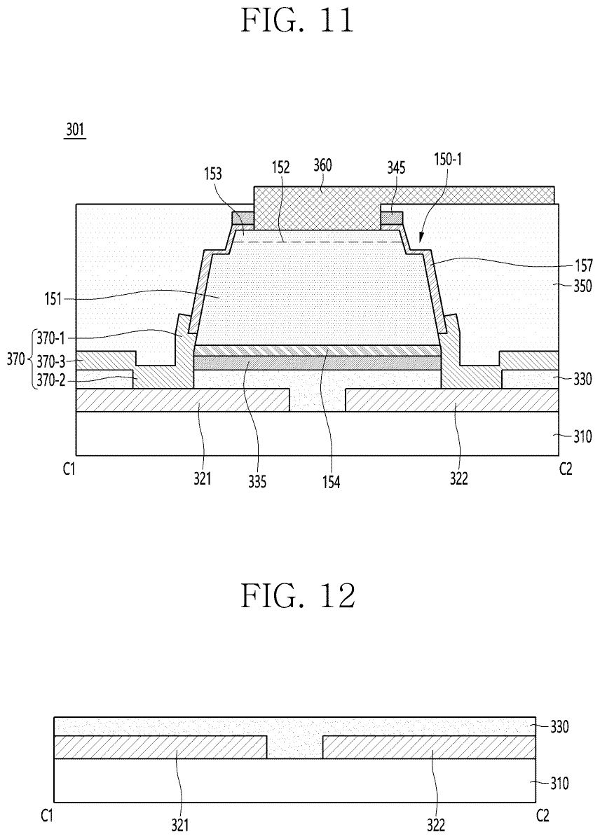

FIG. 10 is a plan view illustrating a display device according to a first embodiment. FIG. 11 is a cross-sectional view taken along the C1-C2 line of FIG. 10.

Referring to FIGS. 10 and 11, the display device 301 according to the first embodiment may comprise a substrate 310, a first assembly wiring 321, a second assembly wiring 322, a first insulating layer 330, a plurality of semiconductor light-emitting elements 150-1 to 150-3, a second insulating layer 335, a connecting electrode 370, a third insulating layer 345, a fourth insulating layer 350, and an electrode wiring 360. The display device 301 according to the first embodiment may comprise more components than these, but is not limited thereto. Although not illustrated, a second substrate may be provided as an upper substrate on the electrode wiring 360. The second substrate may be made of a rigid or flexible material. The second substrate may be made of a transparent or opaque material.

The substrate 310 may serve as a supporting member supporting various components of the display device 301.

A plurality of subpixels PX1, PX2, and PX3 may be defined on the substrate 310. For example, a unit pixel PX may be configured by a first subpixel PX1, a second subpixel PX2, and a third subpixel PX3.

A first assembly wiring 321, a second assembly wiring 322, a first insulating layer 330, semiconductor light-emitting elements 150-1 to 150-3, a second insulating layer 335, a connecting electrode 370, a third insulating layer 345, a fourth insulating layer 350, and an electrode wiring 360 may be sequentially disposed on the plurality of subpixels PX1, PX2, and PX3, respectively, of the substrate 310.

The display device 301 according to the first embodiment may assemble the semiconductor light-emitting elements 150-1 to 150-3 on the plurality of subpixels PX1, PX2, and PX3, respectively, using a self-assembly method.

A backplane substrate may be provided to assemble the semiconductor light-emitting elements 150-1 to 150-3 on the plurality of subpixels PX1, PX2, and PX3, respectively, using the self-assembly method.

For example, the backplane substrate may be manufactured by the manufacturing process illustrated in FIGS. 12 to 15B. Accordingly, the backplane substrate may comprise the substrate 310, the first assembly wiring 321, the second assembly wiring 322, the first insulating layer 330, and the partition wall 340.

As will be described later, after the plurality of semiconductor light-emitting elements 150-1 to 150-3 are assembled into the plurality of subpixels PX1, PX2, and PX3, respectively, the partition wall 340 may be removed. That is, after a plurality of semiconductor light-emitting elements 150-1 to 150-3 are assembled into a plurality of assembly holes 340H of the partition wall 340, a connecting electrode 370 may be formed on a lateral part of the first conductivity type semiconductor layers 151 and/or the electrodes 154 for electrical connection with the first conductivity type semiconductor layers 151 and/or the electrodes 154 of the plurality of semiconductor light-emitting elements 150-1 to 150-3. However, since the gap between the outer side of each of the plurality of semiconductor light-emitting elements 150-1 to 150-3 and the inner side of the assembly hole 340H is very narrow, a disconnection occurs in the connecting electrode 370. To solve this problem, after a plurality of semiconductor light-emitting elements 150-1 to 150-3 are assembled into the plurality of subpixels PX1, PX2, and PX3, respectively, the partition wall 340 may be removed. Accordingly, since there is no obstacle on the lateral part of each of the plurality of semiconductor light-emitting elements 150-1 to 150-3, a disconnection does not occur in the connecting electrode 370.

Referring again to FIG. 10 and FIG. 11, the first assembly wiring 321 and the second assembly wiring 322 may be disposed on the substrate 310. The first assembly wiring 321 and the second assembly wiring 322 may dispose the semiconductor light-emitting elements 150-1 to 150-3 in the plurality of subpixels PX1, PX2, and PX3, respectively. For example, the first assembly wiring 321 and the second assembly wiring 322 may be disposed in the same layer. For example, the first assembly wiring 321 and the second assembly wiring 322 may be in contact with the upper surface of the substrate 310, but is not limited thereto. For example, the first assembly wiring 321 and the second assembly wiring 322 may be disposed parallel to each other.

The first assembly wiring 321 and the second assembly wiring 322 are members for forming a DEP force, and the semiconductor light-emitting elements 150-1 to 150-3 may be assembled to the plurality of subpixels PX1, PX2, and PX3, respectively, by using the DEP force during self-assembly. That is, the semiconductor light-emitting elements 150-1 to 150-3 flowing in the fluid may be pulled by the DEP force and assembled to the plurality of subpixels PX1, PX2, and PX3, respectively.

The first insulating layer 330 may be disposed on the first assembly wiring 321 and the second assembly wiring 322. For example, the first insulating layer 330 may be made of an inorganic material or an organic material. For example, the first insulating layer 330 may be made of a material having a permittivity related to the DEP force, and may contribute to the intensity of the DEP force formed between the first assembly wiring 321 and the second assembly wiring 322. The first insulating layer 330 may protect the first assembly wiring 321 and the second assembly wiring 322.

A plurality of semiconductor light-emitting elements 150-1 to 150-3 may be disposed on the substrate 310. The plurality of semiconductor light-emitting elements 150-1 to 150-3 may be disposed in a plurality of subpixels PX1, PX2, and PX3, respectively, of the substrate 310. For example, the first semiconductor light-emitting element 150-1 may be disposed in the first subpixel PX1, the second semiconductor light-emitting element 150-2 may be disposed in the second subpixel PX2, and the third semiconductor light-emitting element 150-3 may be disposed in the third subpixel PX3.

The plurality of semiconductor light-emitting elements 150-1 to 150-3 may emit different color light to display an image. For example, the first semiconductor light-emitting element 150-1 on the first subpixel PX1 may emit the first color light, i.e., red light, the second semiconductor light-emitting element 150-2 on the second subpixel PX2 may emit green light, and the third semiconductor light-emitting element 150-3 on the third subpixel PX3 may emit blue light, but is not limited thereto.

As an example, during self-assembly, the first semiconductor light-emitting element 150-1, the second semiconductor light-emitting element 150-2, and the third semiconductor light-emitting element 150-3 dispersed in the chamber (1300 of FIG. 9) may be simultaneously moved by the same assembly device 1100 and assembled into the corresponding subpixels PX1, PX2, and PX3, respectively.

As another example, during self-assembly, the first semiconductor light-emitting element 150-1, the second semiconductor light-emitting element 150-2, and the third semiconductor light-emitting element 150-3 may be sequentially assembled into the corresponding subpixels PX1, PX2, and PX3, respectively. For example, the first semiconductor light-emitting element 150-1 may be assembled into the first subpixel PX1, then the second semiconductor light-emitting element 150-2 may be assembled into the second subpixel PX2, and then the third semiconductor light-emitting element 150-3 may be assembled into the third subpixel PX3.

The plurality of semiconductor light-emitting elements 150-1 to 150-3 may have different shapes to increase the assembly speed and improve the assembly rate, but is not limited thereto.

The plurality of semiconductor light-emitting elements 150-1 to 150-3 of the embodiment may be vertical-type semiconductor light-emitting elements, but is not limited thereto.

The plurality of semiconductor light-emitting elements 150-1 to 150-3 may have a similar or identical structure except for the material of the semiconductor layer.

The plurality of semiconductor light-emitting elements 150-1 to 150-3 may each comprise a light-emitting layer 151, 152, and 153, an electrode 154, and a passivation layer 157. The plurality of semiconductor light-emitting elements 150-1 to 150-3 may each comprise more components than these.

The light-emitting layer 151, 152, and 153 may comprise at least one or more first conductivity type semiconductor layer 151, an active layer 152, and at least one or more second conductivity type semiconductor layer 153, but may comprise more components than these. The first conductivity type semiconductor layer 151 may comprise a first conductive dopant, and the second conductivity type semiconductor layer 153 may comprise a second conductive dopant. For example, the first conductive dopant may be an n-type dopant such as silicon (Si), and the second conductive dopant may be a p-type dopant such as boron (B).

The electrode 154 may be disposed on the lower side of the first conductivity type semiconductor layer 151. The electrode 154 may comprise at least one or more layer. For example, the electrode 154 may comprise an ohmic layer (or ohmic contact layer), a reflective layer, a magnetic layer, a conductive layer (or electrode layer), an anti-oxidation layer, an adhesive layer, etc. For example, a part or all of the ohmic layer may be in contact with the first conductivity type semiconductor layer 151. The ohmic layer may comprise Au, AuBe, etc. A part or all of the reflective layer may comprise Al, Ag, etc. The magnetic layer may comprise Ni, Co, etc. The conductive layer may comprise Cu, etc. The anti-oxidation layer may be in contact with the lower surface of the conductive layer to prevent corrosion of the conductive layer. The anti-oxidation layer may comprise Mo, etc. The adhesive layer may be disposed between the ohmic layer and the reflective layer, between the ohmic layer and the magnetic layer, between the ohmic layer and the conductive layer, between the reflective layer and the conductive layer, etc. The adhesive layer may comprise Cr, Ti, etc.

Although not illustrated, the electrode 154 may be disposed on the lateral part of the first conductivity type semiconductor layer 151 for electrical contact with the connecting electrode 370.

Although not illustrated, another electrode (second electrode) may be disposed on the upper side of the second conductivity type semiconductor layer 153. The second electrode may also comprise a transparent conductive layer such as ITO.

The passivation layer 157 may protect the light-emitting layer 151, 152, and 153. For example, the passivation layer 157 may surround the light-emitting layer 151, 152, and 153. The passivation layer 157 has a permittivity, and thus may affect the intensity of the DEP force formed between the first assembly wiring 321 and the second assembly wiring 322 during self-assembly.

Meanwhile, an attractive force may be applied to the electrodes 154 of the plurality of semiconductor light-emitting elements 150-1 to 150-3, and a repulsive force may be applied to the passivation layer 157 in response to the DEP force formed on the first assembly wiring 321 and the second assembly wiring 322. Accordingly, since the electrode 154 is disposed on the lower side of the light-emitting layer 151, 152, and 153, and the remaining lateral part of the light-emitting layer 151, 152, and 153 may be surrounded by the passivation layer 157, the first conductivity type semiconductor layer 151 of each of the plurality of semiconductor light-emitting elements 150-1 to 150-3 may be adjusted to face the first assembly wiring 321 and the second assembly wiring 322, and the second conductivity type semiconductor layer 153 may face forward, by the DEP force formed in each of the plurality of subpixels PX1, PX2, and PX3. Therefore, the semiconductor light-emitting elements 150-1 to 150-3 may be properly assembled to the plurality of subpixels PX1, PX2, and PX3, respectively, without being flipped over.

Meanwhile, after the plurality of semiconductor light-emitting elements 150-1 to 150-3 are assembled into the plurality of subpixels PX1, PX2, and PX3, respectively, using the self-assembly method, an electrical connection process may be performed to form the connecting electrode 370 and the electrode wiring 360.

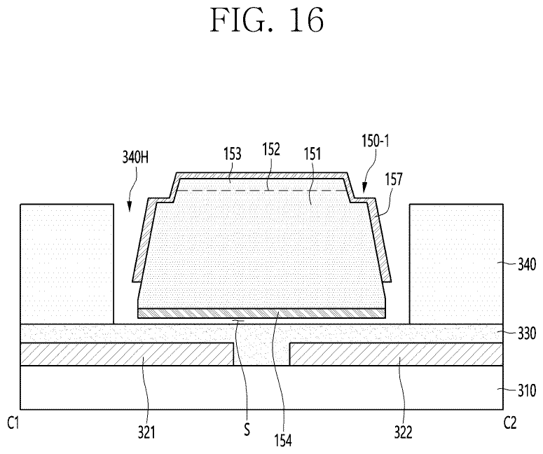

After the plurality of semiconductor light-emitting elements 150-1 to 150-3 are assembled into the plurality of subpixels PX1, PX2, and PX3, respectively, before performing the electrical connection process, the fluid 1200 in the chamber (1300 of FIG. 9) may be drained, the substrate 310 may be detached from the chamber 1300, the substrate 310 may be dried, and the partition wall (340 of FIG. 16) on the substrate 310 can be removed. Even if these series of processes are performed, the plurality of semiconductor light-emitting elements 150-1 to 150-3 assembled in the plurality of subpixels PX1, PX2, and PX3, respectively, must be stably fixed. To this end, in the embodiment, the second insulating layer 335 may be formed before these series of processes are performed and the electrical connection process is performed, so that the plurality of semiconductor light-emitting elements 150-1 to 150-3 can be stably fixed to the plurality of subpixels PX1, PX2, and PX3, respectively, by the second insulating layer 335.

Each of the plurality of semiconductor light-emitting elements 150-1 to 150-3 may have a size of 5 micrometers or less. The smaller the size of each of the plurality of semiconductor light-emitting elements 150-1 to 150-3, the more difficult it is to form the connecting electrode 370 on the lateral part of each of the plurality of semiconductor light-emitting elements 150-1 to 150-3. Moreover, it is very difficult to form the connecting electrode 370 on the lateral part of each of the plurality of semiconductor light-emitting elements 150-1 to 150-3 after each of the plurality of semiconductor light-emitting elements 150-1 to 150-3 is assembled into the plurality of assembly holes 340H of the partition wall 340. However, as will be explained later, since the partition wall is made of an organic material in a conventional technology, when an ashing process is performed to remove the partition wall, the etching rate of the ashing process is very slow and the process time is very long. In contrast, in the embodiment, by patterning a photosensitive film comprising a photosensitive material using a photolithography process, the second insulating layer 335 and the third insulating layer 340 may be formed while simultaneously removing the partition wall 340, so that the process can be dramatically simplified and the process time can be significantly shortened.

The second insulating layer 335 may be a fixed layer, and may be a fixing member for stably fixing the plurality of semiconductor light-emitting elements 150-1 to 150-3 to the plurality of subpixels PX1, PX2, and PX3, respectively.

As will be explained later, since the partition wall 340 is removed simultaneously with the formation of the second insulating layer 335, the process can be simplified and the process time can be shortened.

The second insulating layer 335 may be disposed between the semiconductor light-emitting elements 150-1 to 150-3 and the first insulating layer 330. The second insulating layer 335 may have a shape corresponding to the shape of the semiconductor light-emitting elements 150-1 to 150-3. For example, the diameter (or width) of the second insulating layer 335 may be the same as the diameter (or width) of the semiconductor light-emitting elements 150-1 to 150-3, but is not limited thereto. For example, the second insulating layer 335 may have a shape corresponding to the shape of the first conductivity type semiconductor layers 151 of the semiconductor light-emitting elements 150-1 to 150-3 and/or the shape of the electrode 154. For example, the thickness of the second insulating layer 335 may be smaller than the thickness of the first insulating layer 330. For example, the thickness of the second insulating layer 335 may be smaller than the thickness of the electrode 154 of each of the semiconductor light-emitting elements 150-1 to 150-3.

The connecting electrode 370 may be disposed on the lateral part of each of the plurality of semiconductor light-emitting elements 150-1 to 150-3. The connecting electrode 370 may be electrically connected to the lateral part of each of the plurality of semiconductor light-emitting elements 150-1 to 150-3. The connecting electrode 370 may be electrically connected to the lateral part of the electrode 154 of each of the plurality of semiconductor light-emitting elements 150-1 to 150-3. The connecting electrode 370 may be electrically connected to the lateral part of the first conductivity type semiconductor layer 151 of each of the plurality of semiconductor light-emitting elements 150-1 to 150-3.

For example, the thickness of the connecting electrode 370 may be greater than the thickness of the first insulating layer 330. For example, the thickness of the connecting electrode 370 may be greater than the thickness of the electrode 154 of each of the plurality of semiconductor light-emitting elements 150-1 to 150-3.

For example, the connecting electrode 370 may be formed of at least one or more layer having excellent electrical conductivity. For example, the connecting electrode 370 may comprise, but is not limited to, a first layer comprising molybdenum (Mo), a second layer comprising aluminum (Al), and a third layer comprising molybdenum (Mo).

For example, a first side of the connecting electrode 370 may be electrically connected to the first assembly wiring 321 and/or the second assembly wiring 322 via the first insulating layer 330, and a second side of the connecting electrode 370 may be electrically connected to the lateral part of the semiconductor light-emitting elements 150-1 to 150-3.

The connecting electrode 370 may comprise a first connecting electrode 370-1 on the lateral part of each of the plurality of semiconductor light-emitting elements 150-1 to 150-3, a second connecting electrode 370-2 on the first assembly wiring 321 and/or the second assembly wiring 322, and a third connecting electrode 370-3 on the first insulating layer 330.

The first connecting electrode 370-1 may be disposed along the perimeter of a lateral part of each of the plurality of semiconductor light-emitting elements 150-1 to 150-3. The first connecting electrode 370-1 may be electrically connected to the lateral part of the light-emitting layer 151, 152, and 153 along the perimeter of a lateral part of each of the plurality of semiconductor light-emitting elements 150-1 to 150-3. The first connecting electrode 370-1 may be electrically connected to the lateral part of the electrode 154 of each of the plurality of semiconductor light-emitting elements 150-1 to 150-3. The first connecting electrode 370-1 may be in contact with the lateral part of the electrodes 154 of the plurality of semiconductor light-emitting elements 150-1 to 150-3. The first connecting electrode 370-1 may be electrically connected to the lateral part of the first conductivity type semiconductor layer 151 of each of the plurality of semiconductor light-emitting elements 150-1 to 150-3. The first connecting electrode 370-1 may be in contact with the lateral part of the first conductivity type semiconductor layer 151 of each of the plurality of semiconductor light-emitting elements 150-1 to 150-3.

The second connecting electrode 370-2 may be electrically connected to the first connecting electrode 370-1. The second connecting electrode 370-2 may extend from the first connecting electrode 370-1 in an outward direction of each of the plurality of semiconductor light-emitting elements 150-1 to 150-3. The second connecting electrode 370-2 may be disposed on the first assembly wiring 321 and/or the second assembly wiring 322 through the first insulating layer 330. The second connecting electrode 370-2 may be electrically connected to the first assembly wiring 321 and/or the second assembly wiring 322 through the first insulating layer 330. The second connecting electrode 370-2 may be in contact with the upper surface of the first assembly wiring 321 and/or the second assembly wiring 322 through the first insulating layer 330.

The third connecting electrode 370-3 may be electrically connected to the second connecting electrode 370-2. The third connecting electrode 370-3 may extend from the second connecting electrode 370-2 in an outward direction of each of the plurality of semiconductor light-emitting elements 150-1 to 150-3. The third connecting electrode 370-3 may be disposed on the first insulating layer 330. The third connecting electrode 370-3 may be in contact with the upper surface of the first insulating layer 330. The third connecting electrode 370-3 may be omitted.

Meanwhile, a part of the connecting electrode 370 may extend from the first connecting electrode 370-1 along the lateral part of each of the plurality of semiconductor light-emitting elements 150-1 to 150-3 toward the upper side of each of the plurality of semiconductor light-emitting elements 150-1 to 150-3. An end of a part of the connecting electrode 370 may be positioned lower than the active layer 152, but is not limited thereto. A part of the connecting electrode 370 may be disposed on a part of a passivation layer 157 disposed on the lateral part of the light-emitting layer 151, 152, and 153 of each of the plurality of semiconductor light-emitting elements 150-1 to 150-3. A part of the connecting electrode 370 may be in contact with a part of a passivation layer 157 disposed on the lateral part of the light-emitting layer 151, 152, and 153 of each of the plurality of semiconductor light-emitting elements 150-1 to 150-3.

Accordingly, current from each of the semiconductor light-emitting elements 150-1 to 150-3 may flow to the first assembly wiring 321 and/or the second assembly wiring 322 through the connecting electrode 370.

Meanwhile, the electrode wirings 360 may be disposed on the upper side of each of the semiconductor light-emitting elements 150-1 to 150-3, and may be electrically connected to the upper side of the semiconductor light-emitting elements 150-1 to 150-3, respectively.

The electrode wiring 360 may be in contact with the upper surface of the light-emitting layer 151, 152, and 153 through the fourth insulating layer 350 and the passivation layer 157 of each of the semiconductor light-emitting elements 150-1 to 150-3. In this instance, the fixation of the electrode wiring 360 may be weak. In particular, when the fourth insulating layer 350 is not disposed on the upper side of each of the semiconductor light-emitting elements 150-1 to 150-3, the electrode wiring 360 may be only in contact with the upper surface of the light-emitting layer 151, 152, and 153 through the passivation layer 157, so that the fixation of the electrode wiring 360 may be considerably weak.

To solve this problem, the third insulating layer 345 may be disposed on the upper side of each of the semiconductor light-emitting elements 150-1 to 150-3. The fourth insulating layer 350 may be disposed on the third insulating layer 345, but is not limited thereto.

The third insulating layer 345 may be a fixed layer and may be a fixing member for reinforcing the fixation of the electrode wiring 360. That is, since the electrode wiring 360 is connected to the upper side of the light-emitting layer 151, 152, and 153 through the fourth insulating layer 350, the third insulating layer 345, and the passivation layer 157 of each of the semiconductor light-emitting elements 150-1 to 150-3, the electrode wiring 360 can be firmly fixed by the third insulating layer 345, so that the fixation of the electrode wiring 360 can be strengthened.

The third insulating layer 345 may surround the electrode wiring 360. The third insulating layer 345 may surround a lateral surface of a part of the electrode wiring 360.

Meanwhile, the third insulating layer 345 may be a mask or stopper to prevent the fourth insulating layer 350 from being formed on the upper side of each of the semiconductor light-emitting elements 150-1 to 150-3. The fourth insulating layer 350 may be a planarization layer, and its upper surface may have a straight plane.

For example, the fourth insulating layer 350 may be formed relatively thickly over the entire region of the substrate 310 so that its upper surface may have a straight plane. In this instance, the fourth insulating layer 350 may be formed on the upper side of each of the semiconductor light-emitting elements 150-1 to 150-3.

However, when the fourth insulating layer 350 is thick, there is a problem in that the overall thickness of the display device 301 according to the first embodiment also becomes thick. In particular, since the proportion of the fourth insulating layer 350 in the overall thickness of the display device 301 according to the first embodiment is considerably large, it is necessary to reduce the thickness of the fourth insulating layer 350.

For example, the fourth insulating layer 350 may be formed of a low-viscosity organic material that is easy to form a thickness. In this instance, the fourth insulating layer 350 may be removed through an ashing process. At this time, the ashing process may be performed until the third insulating layer 345 disposed on the upper side of each of the semiconductor light-emitting elements 150-1 to 150-3 is exposed. That is, when the third insulating layer 345 is exposed while the ashing process is performed, the ashing process may be stopped. In this instance, the upper surface of the ashing-treated fourth insulating layer 350 may be positioned on the same horizontal line as the upper surface of the third insulating layer 345. Accordingly, the third insulating layer 345 may be used as a mask or stopper to perform the ashing process so that the upper surface of the fourth insulating layer 350 may be formed into a straight plane. By using the third insulating layer 345 as a mask or stopper, the thickness of the fourth insulating layer 350 can be reduced, and also its upper surface may be made to have a straight plane.

Meanwhile, the second insulating layer 335 and the third insulating layer 345 may comprise the same material. For example, the second insulating layer 335 and the third insulating layer 345 may comprise a photosensitive material. In this instance, by using the same photolithography process, the second insulating layer 335 and the third insulating layer 345 may be formed simultaneously, so that the process can be simple and the process time can be shortened. In addition, by using the same photolithography process, not only the second insulating layer 335 and the third insulating layer 345, but also the partition wall 340 may be removed, so that the problem of the process time becoming long in order to remove the partition wall using the ashing process can be solved.

The fourth insulating layer 350 may be disposed on the entire region of the substrate 310. The fourth insulating layer 350 may be disposed on the third insulating layer 345. The fourth insulating layer 350 may be formed of a low-viscosity organic material.

The fourth insulating layer 350 may be a planarization layer, and may prevent a disconnection from occurring when a layer formed on the fourth insulating layer 350, for example, the electrode wiring 360, is formed.

The electrode wiring 360 may be disposed on the fourth insulating layer 350. For example, the electrode wiring 360 may be in contact with the upper surface of the fourth insulating layer 350. When the electrode wiring 360 is not disposed on the third insulating layer 345, the electrode wiring 360 may be disposed on the third insulating layer 345. For example, the electrode wiring 360 may be in contact with the upper surface of the third insulating layer 345.

The electrode wiring 360 may be electrically connected to the upper side of each of the plurality of semiconductor light-emitting elements 150-1 to 150-3 through the fourth insulating layer 350, the third insulating layer 345, and the passivation layer 157 of each of the plurality of semiconductor light-emitting elements 150-1 to 150-3. For example, the electrode wiring 360 may be in contact with the upper surface of the second conductivity type semiconductor layer 153. When a second electrode (not illustrated) is disposed on the second conductivity type semiconductor layer 153, the electrode wiring 360 may be in contact with the upper surface of the second electrode.

FIGS. 12 to 26 illustrate a manufacturing process of a display device according to the first embodiment.

As illustrated in FIG. 12, a first assembly wiring 321 and a second assembly wiring 322 may be formed on a substrate 310. Thereafter, a first insulating layer 330 may be formed on the first assembly wiring 321 and the second assembly wiring 322.

Although the drawing illustrates that the first assembly wiring 321 and the second assembly wiring 322 are formed simultaneously on the same plane, they may be formed separately from each other. For example, they may be formed in the order of the first assembly wiring 321→another insulating layer→the second assembly wiring 322→the first insulating layer 330. Another insulating layer may be formed of the same material as the material of the first insulating layer 330, but is not limited thereto.

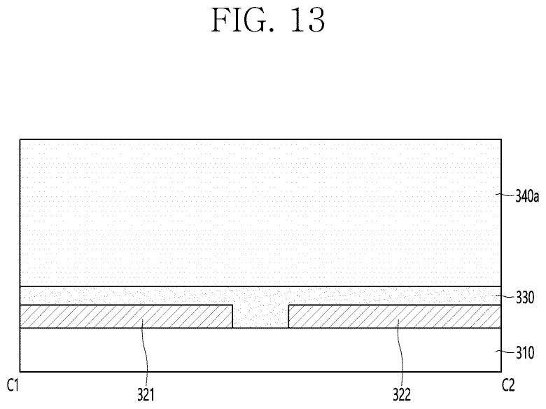

As illustrated in FIG. 13, a photosensitive film 340a may be formed on the first insulating layer 330. For example, the photosensitive film 340a may be formed of a positive photosensitive material. In the photosensitive film 340a, a region irradiated with light may be removed, and a region not irradiated with light may not be removed.

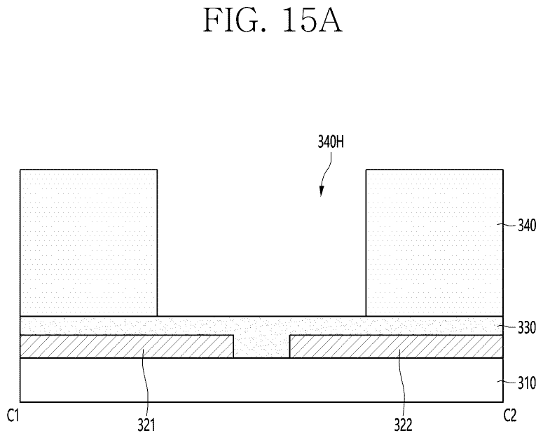

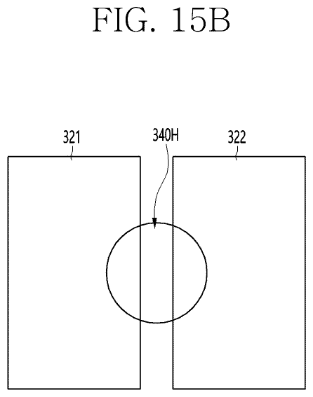

The photosensitive film 340a may constitute a partition wall 340 to form an assembly hole (340H of FIG. 15A and FIG. 15B).

In an existing technology, when the partition wall was made of organic material and the partition was removed through a post-process, there was a problem that the oxidized organic residue film (11 in FIG. 3a) remained, causing the connection electrode (or lateral electrode, 12 in FIG. 3b) to be disconnected or the roughness of the side electrode 12 increased, resulting in an increase in electrical resistance.

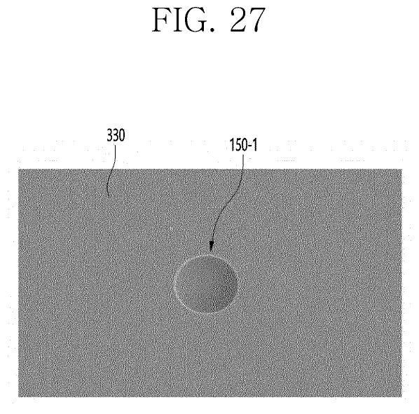

In contrast, in the embodiment, when a photosensitive film 340a made of a positive photosensitive material is used as the partition wall 340, not only is the photosensitive film 340a easily removed by exposure when the partition wall 340 is removed, but also the oxidized organic residue film (11 in FIG. 3A) is not generated on the first insulating layer 330, and the upper surface of the first insulating layer 330 may maintain a clean surface (FIG. 27). Accordingly, the connecting electrode 370 can be easily formed without a disconnection by a post-process.

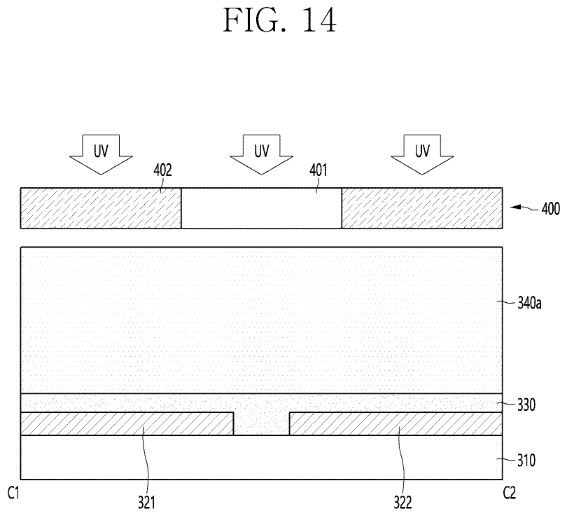

As illustrated in FIGS. 14 and 15, an assembly hole 340H may be formed in the photosensitive film 340a by performing a photolithography process.

That is, as illustrated in FIG. 14, a photomask 400 may be positioned on the photosensitive film 340a. The photomask 400 may comprise a light-transmitting region 401 and a light-shielding region 402. The light-shielding region 402 may surround the light-transmitting region 401. The light-transmitting region 401 may be a region through which light is transmitted, and the light-shielding region 402 may be a region through which light is blocked. For example, the light-transmitting region 401 may have a shape corresponding to the shape of the assembly hole 340H. For example, the light-transmitting region 401 may have a size corresponding to the size of the assembly hole 340H.

An exposure process may be performed on the photomask 400. As light is irradiated on the photomask 400, the light may be irradiated on the photosensitive film 340a corresponding to the light-transmitting region 401 of the photomask 400, and may not be irradiated on the photosensitive film 340a corresponding to the light-transmitting region 401 of the photomask 400.

Thereafter, as the development process is performed, an assembly hole 340H may be formed, as illustrated in FIGS. 15A and 15B. At this time, the photosensitive film 340a may be formed as a partition wall 340. For example, the assembly hole 340H may vertically overlap with a part of the first assembly wiring 321 and a part of the second assembly wiring 322, respectively. For example, the first insulating layer 330 may be exposed by the assembly hole 340H.

Although one assembly hole 340H is illustrated in the drawing, an assembly hole corresponding to each of the plurality of subpixels PX1, PX2, and PX3 of each of the plurality of pixels may be formed in the partition wall 340.

As described above, a backplane substrate may be manufactured by the manufacturing process illustrated in FIGS. 12 to 15B. Such a backplane substrate may be manufactured in advance.

As illustrated in FIG. 16, a self-assembly process may be performed so that the semiconductor light-emitting element 150-1 may be assembled into the assembly hole 340H. As described above, the self-assembly process may mean a series of processes in which a plurality of semiconductor light-emitting elements 150-1 to 150-3 in a fluid of a chamber are assembled into a plurality of assembly holes 340H, respectively, of a partition wall 340 by using a magnetic field by a magnet and an electric field (or DEP force) formed by the first assembly wiring 321 and the second assembly wiring 322.

Although not illustrated in FIG. 16, the plurality of second semiconductor light-emitting elements 150-2 and the plurality of third semiconductor light-emitting elements 150-3 illustrated in FIG. 10 may be assembled into the corresponding assembly holes 340H.

After the semiconductor light-emitting element 150-1 is assembled into the assembly hole 340H, the substrate 310 may be detached from the chamber, and then a drying process may be performed so that the substrate 310, the partition wall 340, the semiconductor light-emitting element 150-1, etc. may be dried. At this time, the semiconductor light-emitting element 150-1 may be fixed by the DEP force and may also be spaced upward from the first insulating layer 330. That is, a predetermined space S may be formed between the first insulating layer 330 and a lower side of the semiconductor light-emitting element 150-1.

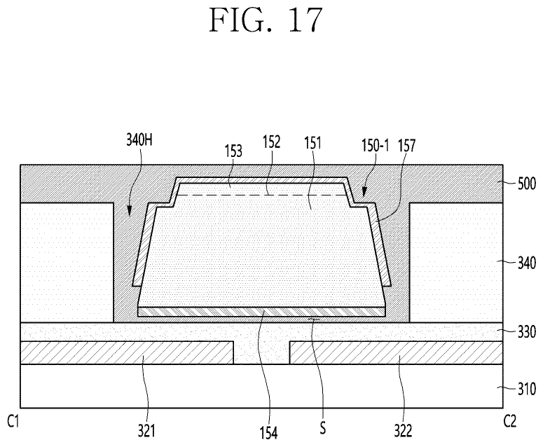

As illustrated in FIG. 17, a photosensitive film 500 may be formed on the partition wall 340. The photosensitive film 500 may be made of a positive photosensitive material. In the photosensitive film 500, a region irradiated with light may be removed, and a region not irradiated with light may not be removed.

The photosensitive film 500 may be formed not only on the partition wall 340 but also on the semiconductor light-emitting element 150-1. That is, the photosensitive film 500 may cover the semiconductor light-emitting element 150-1. In addition, the photosensitive film 500 may be formed in the space S between the first insulating layer 330 and the semiconductor light-emitting element 150-1 within the assembly hole 340H.

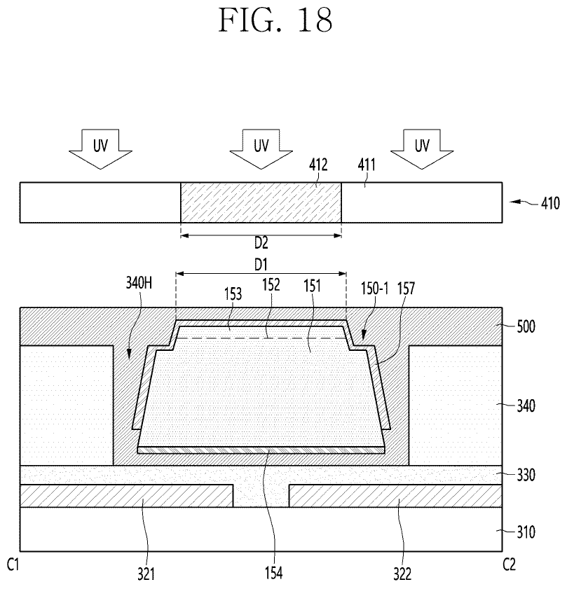

As illustrated in FIG. 18, a photomask 410 may be positioned on a photosensitive film 500. The photomask 410 may comprise a light-transmitting region 411 and a light-shielding region 412. The light-transmitting region 411 may surround the light-shielding region 412. The light-transmitting region 411 may be a region through which light is transmitted, and the light-shielding region 412 may be a region through which light is blocked. For example, the light-shielding region 412 may have a shape corresponding to a shape of an upper side of the semiconductor light-emitting element 150-1. For example, the light-shielding region 412 may have a size (or diameter, D2) that is equal to or smaller than a size (or diameter, D1) of an upper side of the semiconductor light-emitting element 150-1.

An exposure process may be performed on the photomask 410. As light is irradiated to the photomask 410, the light may be irradiated to the photosensitive film 500 corresponding to the light-transmitting region 411 of the photomask 410, and may not be irradiated to the photosensitive film 500 corresponding to the light-transmitting region 411 of the photomask 410.

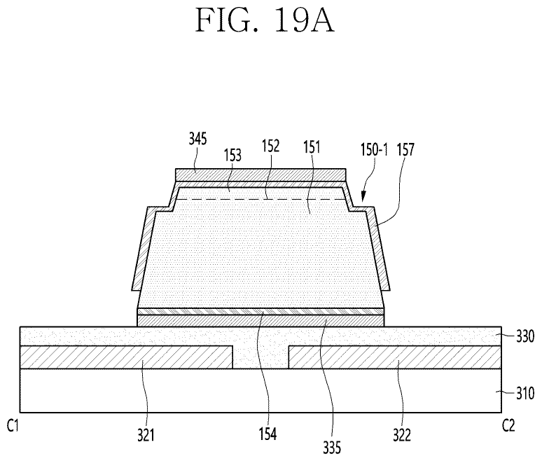

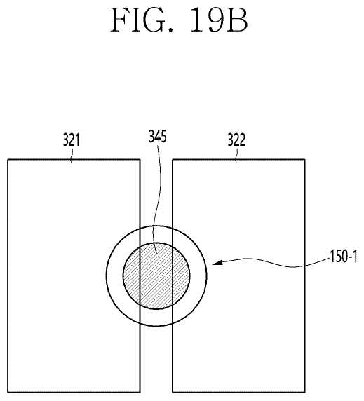

Thereafter, as the development process is performed, the second insulating layer 335 and the third insulating layer 345 may be formed on the lower and upper sides, respectively, of the semiconductor light-emitting element 150-1 as illustrated in FIGS. 19A and 19B.

During the exposure process, the photosensitive film 500 filled in the space S between the first insulating layer 330 and the semiconductor light-emitting element 150-1 may not be irradiated with light, and thus may not be removed by the development process, and may be formed as the second insulating layer 335.

When light is irradiated vertically during the exposure process, the photosensitive film 500 corresponding to the shape of the lower side of the semiconductor light-emitting element 150-1 may be formed as the second insulating layer 335, so that the shape of the second insulating layer 335 may have a shape corresponding to the shape of the lower side of the semiconductor light-emitting element 150-1. For example, the second insulating layer 335 may be the same size as or smaller than the size of the lower side of the semiconductor light-emitting element 150-1.

The second insulating layer 335 may be a fixed layer. Since the second insulating layer 335 is formed between the first insulating layer 330 and the lower side of the semiconductor light-emitting element 150-1, the semiconductor light-emitting element 150-1 can be firmly fixed to the first insulating layer 330 by the second insulating layer 335.

As described above, since the light-shielding region 412 of the photomask 410 has a size D2 that is equal to or smaller than the size D1 of the upper side of the semiconductor light-emitting element 150-1, the size (or diameter) of the third insulating layer 345 formed by the exposure process and the development process may be equal to or smaller than the size (or diameter, D1) of the upper side of the semiconductor light-emitting element 150-1. In this instance, the diameter of the third insulating layer 345 may be equal to the diameter D2 of the light-shielding region 412 of the photomask 410, but is not limited thereto.

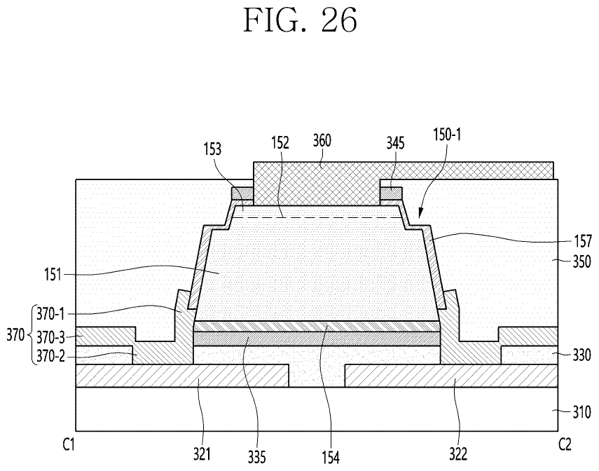

The third insulating layer 345 may be a fixed layer. As will be described later, the electrode wiring (360 of FIG. 26) can be firmly fixed to the upper side of the semiconductor light-emitting element 150-1 by the third insulating layer 345. That is, since the third insulating layer 345 wraps the perimeter of a lateral part of the electrode wiring 360, the electrode wiring 360 can be more firmly fixed to the upper side of the semiconductor light-emitting element 150-1.

Meanwhile, the partition wall 340 may also be removed by the exposure process and the development process. Since the partition wall 340 and the photosensitive film 500 are made of a positive photosensitive material, the partition wall 340 and the photosensitive film 500 that are not exposed may be removed together by the development process. In addition, since the partition wall 340 and the photosensitive film 500 are made of a positive photosensitive material, the first insulating layer 330 that is exposed by removing the partition wall 340 and the photosensitive film 500 through the development process may be maintained as a clean surface, as illustrated in FIG. 27. Accordingly, the connecting electrode 370 can be easily formed without a disconnection by the post-process.

Accordingly, the semiconductor light-emitting element 150-1 may be fixed to the second insulating layer 335 by the second insulating layer 335, and no obstacles exist on the lateral part of the semiconductor light-emitting element 150-1, so that, as will be described later, the formation of the connecting electrode 370 on the lateral part of the semiconductor light-emitting element 150-1 can be very easy and defects in electrical disconnection can be prevented.

According to the embodiment, not only the second insulating layer 335 and the third insulating layer 345 may be formed by the exposure process and the development process, but also the partition wall 340 may be removed, so that additional processes for individually processing these components are not required. Thus, the process can be simplified and the process time can be drastically shortened.

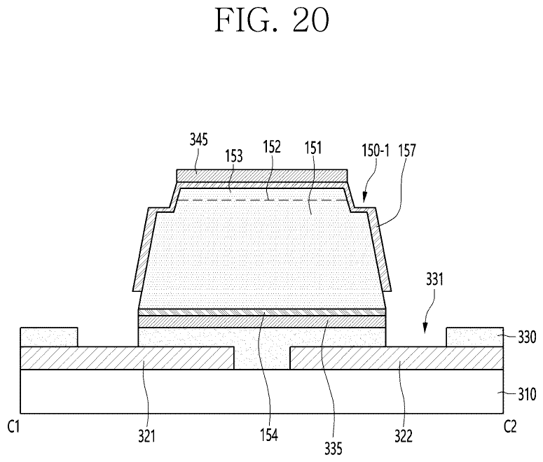

As illustrated in FIG. 20, a patterning process may be performed using a pattern mask (not illustrated), so that the first insulating layer 330 may be removed along the perimeter of the semiconductor light-emitting element 150-1 to form an opening 331. A part of the upper surface of the first assembly wiring 321 and/or the second assembly wiring 322 may be exposed by the opening 331.

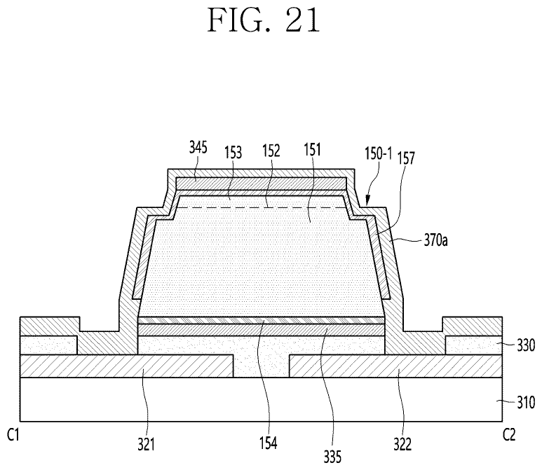

As illustrated in FIG. 21, a metal film 370a may be formed on the entire region of the substrate 310. The metal film 370a may be composed of multiple metals in a multilayer configuration. Since there is no obstacle on the lateral part of the semiconductor light-emitting element 150-1, the metal film 370a may be evenly formed on the entire region of the substrate 310 without a disconnection.

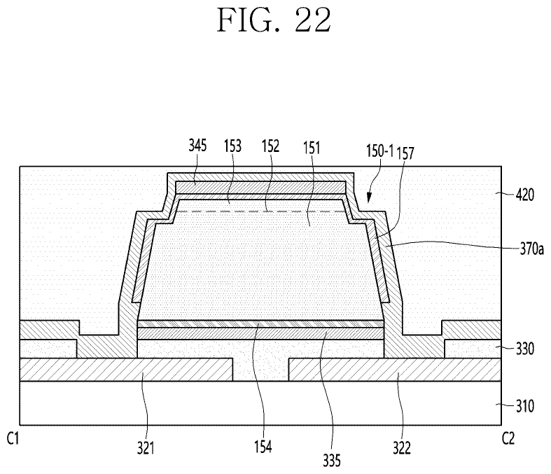

As illustrated in FIG. 22, an organic film 420 may be formed on the metal film 370a. The organic film 420 may be formed on the entire region of the metal film 370a. The organic film 420 may be formed of an organic material that is easy to form a thickness. For example, the organic film 420 may be formed of a low-viscosity organic material.

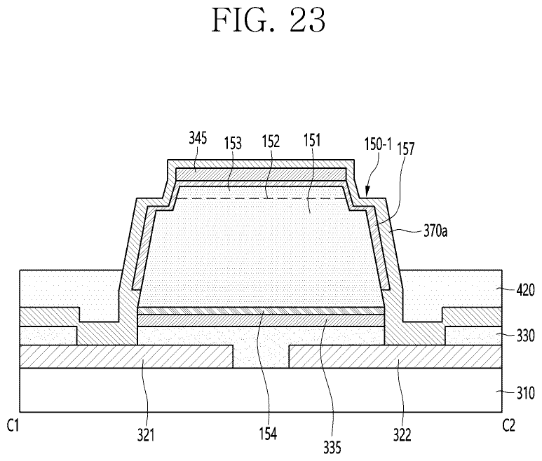

As illustrated in FIG. 23, an ashing process may be performed to remove the upper part of the organic film 420, thereby reducing the thickness of the organic film 420. The upper surface of the organic film 420, whose thickness is reduced, may be positioned lower than the active layer 152 of the semiconductor light-emitting element 150-1, but is not limited thereto.

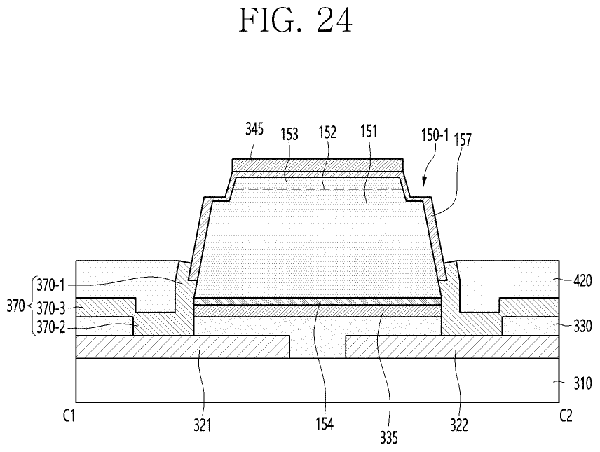

Thereafter, an etching process may be performed using the organic film 420, whose thickness is reduced, as a mask, thereby removing the metal film 370a. Thus, the connecting electrode 370 may be formed, as illustrated in FIG. 24. That is, since the metal film 370a exposed and not protected by the organic film 420 with the reduced thickness is removed, the metal film 370a protected by the organic film 420 may be formed as the connecting electrode 370. The connecting electrode 370 may comprise a first connecting electrode 370-1 on the lateral part of the semiconductor light-emitting element 150-1, a second connecting electrode 370-2 on the first assembly wiring 321 and/or the second assembly wiring 322, and a third connecting electrode 370-3 on the first insulating layer 330.

The organic film 420 with the reduced thickness may serve as a stopper to prevent the metal film 370a covered by the organic film 420 from being etched.

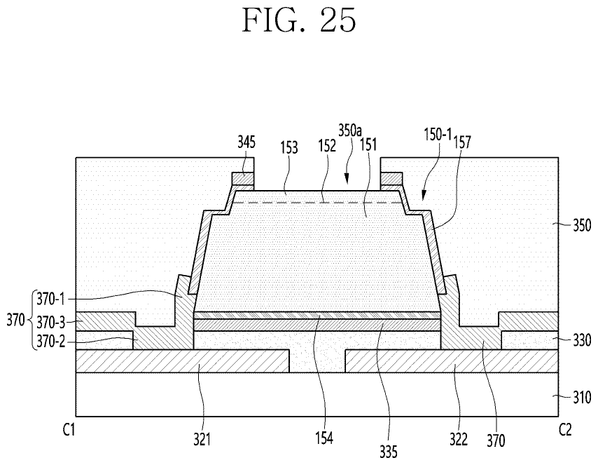

As illustrated in FIG. 25, an organic film, i.e., a fourth insulating layer 350, may be formed on the entire region of the substrate 310. The fourth insulating layer 350 may be formed of the same material as the organic film (420 of FIGS. 23 and 24) used as a mask for forming the connecting electrode 370, but is not limited thereto.

Although not illustrated, the fourth insulating layer 350 may be formed after the organic film 420 is removed, or the fourth insulating layer 350 may be formed on the organic film 420.

Thereafter, a patterning process may be performed, so that a contact hole 350a may be formed in which the upper side of the semiconductor light-emitting element 150-1, that is, the upper surface of the second conductivity type semiconductor layer 153, is exposed. When the contact hole 350a is circular, a circular hole may be formed in each of the fourth insulating layer 350, the third insulating layer 345, and the passivation layer 157 of the semiconductor light-emitting element 150-1.

As illustrated in FIG. 26, an electrode wiring 360 may be formed on the semiconductor light-emitting element 150-1. That is, by forming a metal film on the fourth insulating layer 350, the metal film may be formed not only on the fourth insulating layer 350 but also on the contact hole 350a. Thereafter, a patterning process may be performed, so that the metal film may be formed as an electrode wiring 360 electrically connected to the upper side of the semiconductor light-emitting element 150-1 through the contact hole 350a.

Meanwhile, the third insulating layer 345, together with the fourth insulating layer 350, may allow the electrode wiring 360 to be firmly fixed to the upper side of the semiconductor light-emitting element 150-1. That is, by wrapping the perimeter of a lateral part of the electrode wiring 360 with the third insulating layer 345, the electrode wiring 360 can be more firmly fixed to the upper side of the semiconductor light-emitting element 150-1.

In order to reduce the thickness of the display device 301 according to the first embodiment, the fourth insulating layer 350 may not be formed on the upper side of the semiconductor light-emitting element 150-1. That is, the upper side of the fourth insulating layer 350 may be etched, so that the etched fourth insulating layer 350 may not be formed on the upper side of the semiconductor light-emitting element 150-1 and may be positioned on the same horizontal line as the upper side of the third insulating layer 345. In this instance, even if the fourth insulating layer 350 is not formed on the upper side of the semiconductor light-emitting element 150-1, the electrode wiring 360 can be firmly fixed to the upper side of the semiconductor light-emitting element 150-1 by the third insulating layer 345.

### Second Embodiment

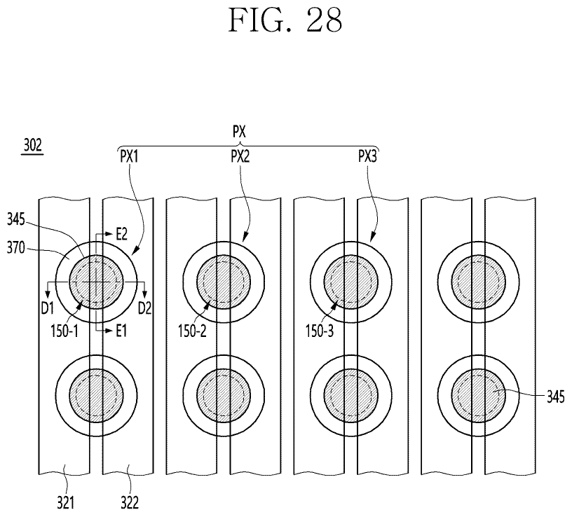

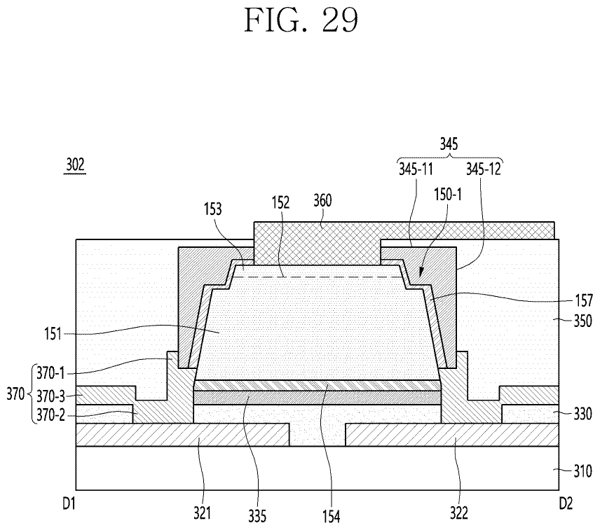

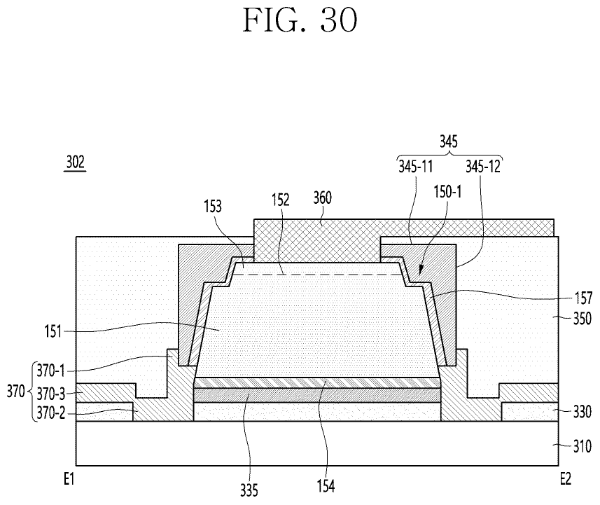

FIG. 28 is a plan view illustrating a display device according to a second embodiment. FIG. 29 is a cross-sectional view of the display device according to the second embodiment of FIG. 28 taken along the line D1-D2. FIG. 30 is a cross-sectional view of the display device according to the second embodiment of FIG. 28 taken along the line E1-E2.

The second embodiment is the same as the first embodiment except for the shape of the third insulating layer 345. In the second embodiment, components having the same shape, structure, and/or function as those in the first embodiment are given the same drawing reference numerals, and detailed descriptions thereof are omitted.

Referring to FIGS. 28 to 30, the display device 302 according to the second embodiment may comprise a substrate 310, a first assembly wiring 321, a second assembly wiring 322, a first insulating layer 330, a plurality of semiconductor light-emitting elements 150-1 to 150-3, a second insulating layer 335, a connecting electrode 370, a third insulating layer 345, a fourth insulating layer 350, and an electrode wiring 360. The display device 302 according to the second embodiment may comprise more components than these, but is not limited thereto.

The electrode wirings 360 may be disposed on the upper sides of the plurality of semiconductor light-emitting elements 150-1 to 150-3, respectively, and may be electrically connected to the upper sides of the plurality of semiconductor light-emitting elements 150-1 to 150-3, respectively. At this time, the electrode wirings 360 may be electrically connected to the upper sides of the plurality of semiconductor light-emitting elements 150-1 to 150-3, respectively, through the fourth insulating layer 350. Since the fourth insulating layer 350 has a large thickness, a reduction in the thickness of the fourth insulating layer 350 is essential in order to reduce the overall thickness of the display device 302 according to the second embodiment. In this instance, the thickness of the fourth insulating layer 350 disposed on the upper side of each of the plurality of semiconductor light-emitting elements 150-1 to 150-3 may be minimized, or the fourth insulating layer 350 may not be formed on the upper side of each of the plurality of semiconductor light-emitting elements 150-1 to 150-3. In this instance, since the electrode wiring 360 does not contact the fourth insulating layer 350, the fixation is weakened and may be peeled off from the upper side of each of the plurality of semiconductor light-emitting elements 150-1 to 150-3.

The third insulating layer 345 of the embodiment may be disposed on the upper side of each of the plurality of semiconductor light-emitting elements 150-1 to 150-3 and disposed along the perimeter of the lateral part of the electrode wiring 360, thereby strengthening the fixation of the electrode wiring 360. When the fourth insulating layer 350 is disposed on the upper side of each of the plurality of semiconductor light-emitting elements 150-1 to 150-3, the fixation of the electrode wiring 360 can be further strengthened by the third insulating layer 345 together with the fourth insulating layer 350.

The third insulating layer 345 may surround each of the plurality of semiconductor light-emitting elements 150-1 to 150-3. The third insulating layer 345 may be disposed on the upper side of each of the plurality of semiconductor light-emitting elements 150-1 to 150-3. The third insulating layer 345 may be disposed along the perimeter of each of the plurality of semiconductor light-emitting elements 150-1 to 150-3.

As illustrated in FIGS. 29 and 30, the third insulating layer 345 may comprise the third-first insulating layer 345-11 and the third-second insulating layer 345-12. The third-first insulating layer 345-11 may be disposed on the upper side of the semiconductor light-emitting element 150-1. The third-second insulating layer 345-12 may extend from the third-first insulating layer 345-11 and surround the lateral part of the semiconductor light-emitting element 150-1. When the semiconductor light-emitting element 150-1 is circular when viewed from above, the third-second insulating layer 345-12 may be disposed along a rounded surface of the lateral part of the semiconductor light-emitting element 150-1.

Meanwhile, the third insulating layer 345 may be connected to the second insulating layer 335. That is, the third insulating layer 345 may be disposed on the upper side of the semiconductor light-emitting element 150-1, and may be connected to the second insulating layer 335 on the lower side of the semiconductor light-emitting element 150-1 via the lateral part of the semiconductor light-emitting element 150-1 from the upper side of the semiconductor light-emitting element 150-1. For example, the third-second insulating layer 345-12 may be in contact with the second insulating layer 335. When the second insulating layer 335 is circular like the semiconductor light-emitting element 150-1, the third-second insulating layer 345-12 may be connected to an end of an edge region of the second insulating layer 335 along the end of the edge region of the second insulating layer 335.

Meanwhile, the connecting electrode 370 may be electrically connected to the lateral part of the semiconductor light-emitting element 150-1 through the third insulating layer 345. For example, an additional exposure process and a development process may be performed along the perimeter of the lower region of the lateral part of the semiconductor light-emitting element 150-1, so that a lower region of the third-second insulating layer 345-12 may be removed, thereby exposing a lower region of the lateral part of the semiconductor light-emitting element 150-1. Thereafter, as the connecting electrode 370 is formed, the connecting electrode 370 may be in contact with the lower region of the lateral part of the semiconductor light-emitting element 150-1, that is, the lateral surface of the electrode 154 and/or the first conductivity type semiconductor layer 151. The connecting electrode 370 may be disposed on the lower region of the third-second insulating layer 345-12. That is, the connecting electrode 370 may horizontally overlap a part of the lower region of the third-second insulating layer 345-12.

In the second embodiment, the arrangement relationship between the first semiconductor light-emitting element 150-1 and the third insulating layer 345 is described, but this arrangement relationship may be equally applied to each of the second semiconductor light-emitting element 150-2 and the third semiconductor light-emitting element 150-3.

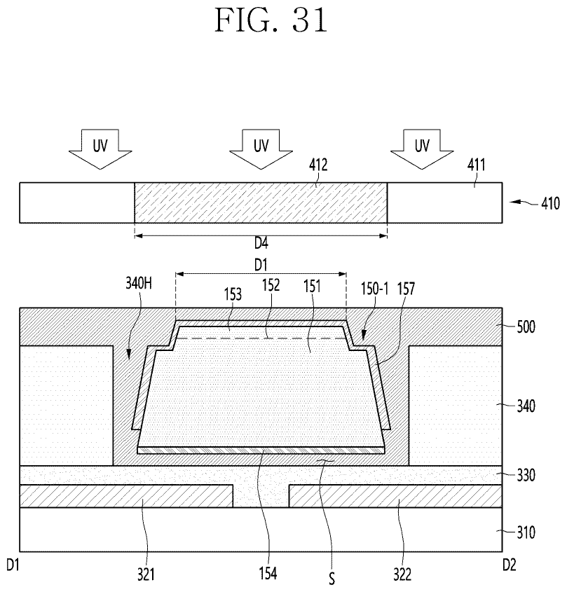

FIGS. 31 to 34 illustrate a manufacturing process of a display device according to the second embodiment.

A semiconductor light-emitting element 150-1 may be assembled on a backplane substrate using a self-assembly method, and a second photosensitive film 500 may be formed on a partition wall 340. Since these series of manufacturing processes have been described above with respect to FIGS. 12 to 17, a detailed description thereof will be omitted.

As illustrated in FIG. 31, a photomask 410 may be positioned on the photosensitive film 500. The photomask 410 may comprise a light-transmitting region 411 and a light-shielding region 412. The light-transmitting region 411 may surround the light-shielding region 412. The light-transmitting region 411 may be a region through which light is transmitted, and the light-shielding region 412 may be a region through which light is blocked. For example, the light-shielding region 412 may have a shape corresponding to a shape of an upper side of the semiconductor light-emitting element 150-1. For example, the light-shielding region 412 may have a size (or diameter, D4) larger than the size (or diameter, D1) of the upper side of the semiconductor light-emitting element 150-1.

A photomask 410 can be subjected to the exposure process. As light is irradiated onto the photomask 410, the light may be irradiated to the photosensitive film 500 corresponding to the light-transmitting region 411 of the photomask 410 and may not be irradiated to the photosensitive film 500 corresponding to the light-transmitting region 411 of the photomask 410.

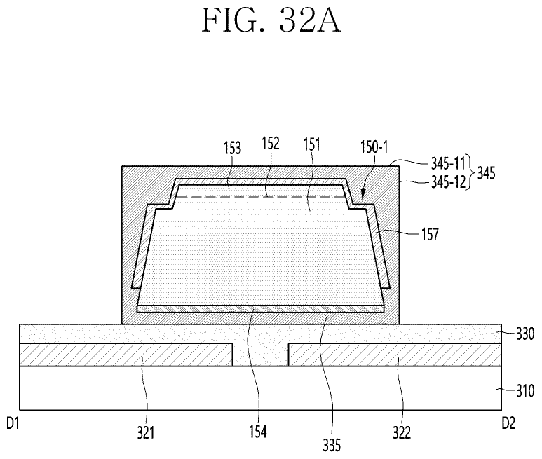

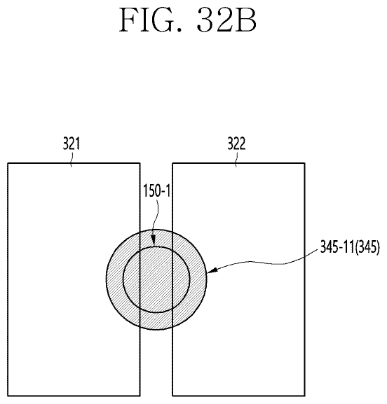

Thereafter, as the development process is performed, the photosensitive film 500 may surround the semiconductor light-emitting element 150-1, as illustrated in FIG. 32A and FIG. 32B. In this way, the photosensitive film 500 covering the semiconductor light-emitting element 150-1 may be formed of a second insulating layer 335 and a third insulating layer 345. The second insulating layer 335 may be formed on the lower side of the semiconductor light-emitting element 150-1. The third insulating layer 345 may be formed on the upper side and the lateral part of the semiconductor light-emitting element 150-1. The third insulating layer 345 may be formed along the perimeter of a lateral part of the semiconductor light-emitting element 150-1. The third insulating layer 345 may comprise a third-first insulating layer 345-11 on the upper side of the semiconductor light-emitting element 150-1, and a third-second insulating layer 345-12 extending from the third-first insulating layer 345-11 and surrounding the lateral part of the semiconductor light-emitting element 150-1.

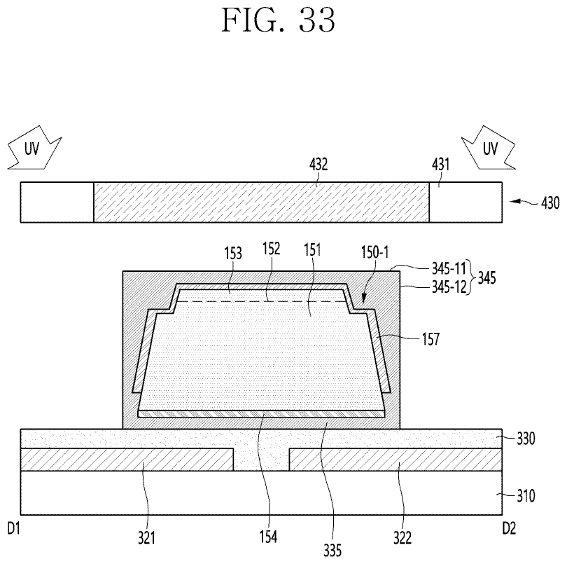

As illustrated in FIG. 33, a photomask 430 may be positioned on the substrate 310. The photomask 430 may comprise a light-transmitting region 431 and a light-shielding region 432. The light-transmitting region 431 may be a region through which light is transmitted, and the light-shielding region 432 may be a region through which light is blocked. For example, the light-shielding region 432 may have a shape corresponding to a shape of an upper side of the semiconductor light-emitting element 150-1. The light-shielding region 432 may have a size such that when light is irradiated in a diagonal direction, the light is irradiated onto a lower region of a sidewall of the semiconductor light-emitting element 150-1 and is not irradiated onto an upper region of the sidewall of the semiconductor light-emitting element 150-1. For example, the light-shielding region 432 may have a size that is twice or more the size of the upper side of the semiconductor light-emitting element 150-1.

After that, an exposure process may be performed so that light may be irradiated in a diagonal direction. The light in the diagonal direction may not be irradiated to the semiconductor light-emitting element 150-1 through the light-shielding region 432 of the photomask 430. The light in the diagonal direction may be irradiated onto the lower region of the lateral part of the semiconductor light-emitting element 150-1 through the transmission area of the photomask 430.

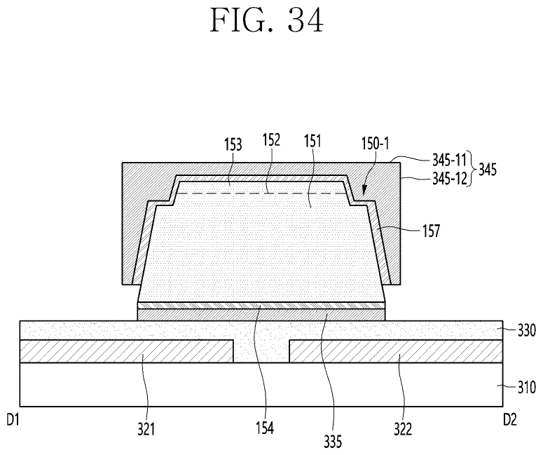

After that, a development process may be performed so that, as illustrated in FIG. 34, the third insulating layer 345, i.e., the third-second insulating layer 345-12, on the lower region of the lateral part of the semiconductor light-emitting element 150-1 may be removed, so that the lower region of the semiconductor light-emitting element 150-1 may be exposed. The exposed lower region of the semiconductor light-emitting element 150-1 may be the electrode 154 and/or the first conductivity type semiconductor layer 151.

Thereafter, although not illustrated, a post-process may be performed so that a connecting electrode 370 may be formed to which the lower region of the exposed semiconductor light-emitting element 150-1 is connected, and an electrode wiring 360 connected to the upper side of the semiconductor light-emitting element 150-1 may be formed. Since these series of manufacturing processes have been described above with respect to FIGS. 20 to 26, a detailed description thereof will be omitted.

### Third Embodiment

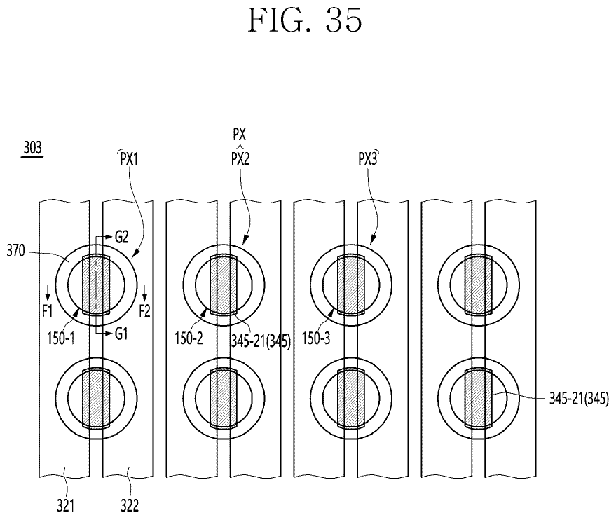

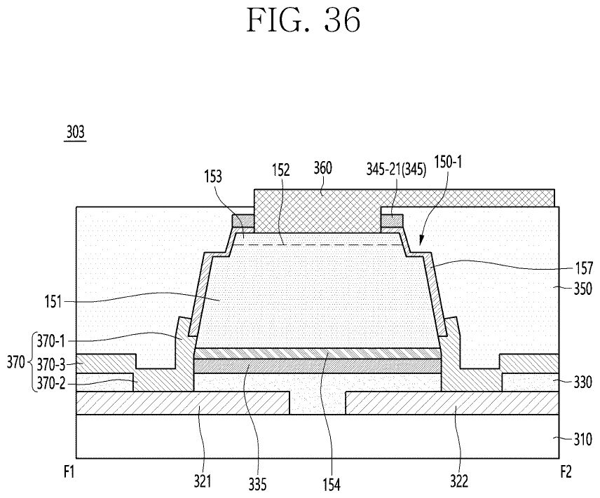

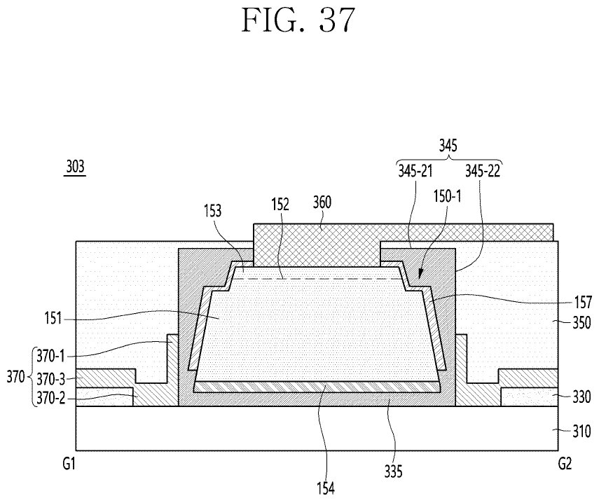

FIG. 35 is a plan view illustrating a display device according to a third embodiment. FIG. 36 is a cross-sectional view of the display device according to the third embodiment of FIG. 35 taken along the line F1-F2. FIG. 37 is a cross-sectional view of the display device according to the third embodiment of FIG. 35 taken along the line G1-G2.

The third embodiment is the same as the first embodiment or the second embodiment except for the shape of the third insulating layer 345. In the third embodiment, components having the same shape, structure, and/or function as those of the first embodiment or the second embodiment are given the same drawing reference numerals, and detailed descriptions thereof are omitted.

Referring to FIGS. 35 to 37, the display device 303 according to the third embodiment may comprise a substrate 310, a first assembly wiring 321, a second assembly wiring 322, a first insulating layer 330, a plurality of semiconductor light-emitting elements 150-1 to 150-3, a second insulating layer 335, a connecting electrode 370, a third insulating layer 345, a fourth insulating layer 350, and an electrode wiring 360. The display device 303 according to the third embodiment may comprise more components than these, but is not limited thereto.

The electrode wirings 360 may be disposed on the upper sides of the plurality of semiconductor light-emitting elements 150-1 to 150-3 and may be electrically connected to the upper sides of the plurality of semiconductor light-emitting elements 150-1 to 150-3. At this time, the electrode wirings 360 may be electrically connected to the upper sides of the plurality of semiconductor light-emitting elements 150-1 to 150-3 through the fourth insulating layer 350. Since the fourth insulating layer 350 has a large thickness, a reduction in the thickness of the fourth insulating layer 350 is essential in order to reduce the overall thickness of the display device 302 according to the third embodiment. In this instance, the thickness of the fourth insulating layer 350 disposed on the upper side of each of the plurality of semiconductor light-emitting elements 150-1 to 150-3 may be minimized, or the fourth insulating layer 350 may not be formed on the upper side of each of the plurality of semiconductor light-emitting elements 150-1 to 150-3. In this instance, since the electrode wiring 360 does not contact the fourth insulating layer 350, the fixation thereof may be weakened, and thus the electrode wiring 360 may be peeled off from the upper side of each of the plurality of semiconductor light-emitting elements 150-1 to 150-3.

The third insulating layer 345 of the embodiment may be disposed on the upper side of each of the plurality of semiconductor light-emitting elements 150-1 to 150-3, and may be disposed along the sidewall perimeter of the electrode wiring 360, thereby reinforcing the fixation of the electrode wiring 360. When the fourth insulating layer 350 is disposed on the upper side of each of the plurality of semiconductor light-emitting elements 150-1 to 150-3, the fixation of the electrode wiring 360 may be further reinforced by the third insulating layer 345 together with the fourth insulating layer 350.

The third insulating layer 345 may partially wrap each of the plurality of semiconductor light-emitting elements 150-1 to 150-3. The third insulating layer 345 may be disposed on the upper side of each of the plurality of semiconductor light-emitting elements 150-1 to 150-3. The third insulating layer 345 may not be disposed on a part of the lateral part of each of the plurality of semiconductor light-emitting elements 150-1 to 150-3 along the perimeter of each of the plurality of semiconductor light-emitting elements 150-1 to 150-3.

As illustrated in FIG. 36 and FIG. 37, the third insulating layer 345 may comprise the third-first insulating pattern 345-21 and the third-second insulating pattern 345-22. The third-first insulating pattern 345-21 may be disposed on the upper side of the semiconductor light-emitting element 150-1. The third-second insulating pattern 345-22 may be disposed on a part of the lateral part of the semiconductor light-emitting element 150-1 by extending from the third-first insulating pattern 345-21. For example, the third-second insulating pattern 345-22 may or may not be disposed along the perimeter of a lateral part of the semiconductor light-emitting element 150-1. As illustrated in FIG. 36, the third-second insulating pattern 345-22 may not be disposed on the lateral part of the semiconductor light-emitting element 150-1. As illustrated in FIG. 37, the third-second insulating pattern 345-22 may be disposed on the lateral part of the semiconductor light-emitting element 150-1.

Meanwhile, the third insulating layer 345 may be connected to the second insulating layer 335. That is, the third insulating layer 345 may be disposed on the upper side of the semiconductor light-emitting element 150-1, and may be connected to the second insulating layer 335 on the lower side of the semiconductor light-emitting element 150-1 via the lateral part of the semiconductor light-emitting element 150-1 from the upper side of the semiconductor light-emitting element 150-1. For example, the third-second insulating pattern 345-22 may be in contact with the second insulating layer 335. When the second insulating layer 335 is circular like the semiconductor light-emitting element 150-1, the third-second insulating pattern 345-22 may be connected to an end of an edge region of the second insulating layer 335 along the end of the edge region of the second insulating layer 335.

Meanwhile, the connecting electrode 370 may be disposed on the lateral part of the semiconductor light-emitting element 150-1. In this instance, the connecting electrode 370 may be in contact with the lateral part of the semiconductor light-emitting element 150-1, that is, the electrode 154 and/or the first conductivity type semiconductor layer 151. The connecting electrode 370 may be in contact with the third insulating layer 345 on the lateral part of the semiconductor light-emitting element 150-1, that is, the third-second insulating pattern 345-22.

Therefore, the third insulating layer 345, together with the second insulating layer 335, can more firmly fix the semiconductor light-emitting element 150-1 to the first insulating layer 330 and wrap the lateral part of the electrode wiring 360 to strengthen the fixation of the electrode wiring 360. In addition, since the third insulating layer 345, i.e., the third-second insulating pattern 345-22, is not disposed, a part of the lateral part of the semiconductor light-emitting element 150-1 may be exposed, so that the connecting electrode 370 can be easily formed in the exposed part of the lateral part of the semiconductor light-emitting element 150-1. In addition, since a sufficient contact area is secured between the connecting electrode 370 and the semiconductor light-emitting element 150-1, the electrical characteristics can be improved.

### Fourth Embodiment

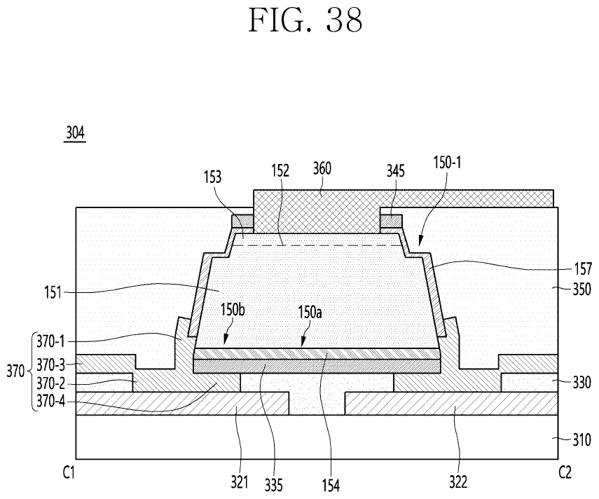

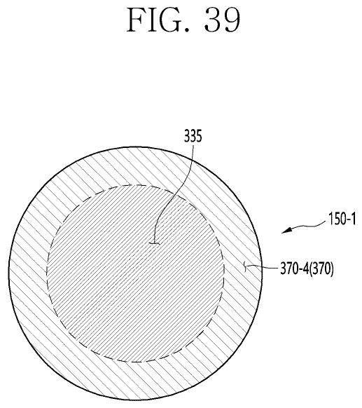

FIG. 38 is a cross-sectional view illustrating a display device according to a fourth embodiment. FIG. 39 illustrates the arrangement relationship of the semiconductor light-emitting element, the second insulating layer, and the fourth connecting electrode.

The fourth embodiment is the same as the first embodiment except for the shape of the second insulating layer 335. In the fourth embodiment, components having the same shape, structure, and/or function as those of the first embodiment are given the same drawing reference numerals, and detailed descriptions thereof are omitted. Meanwhile, the shape of the third insulating layer 345 of the fourth embodiment may be applied equally to the second or third embodiment.

Referring to FIGS. 38 and 39, the display device 304 according to the fourth embodiment may comprise a substrate 310, a first assembly wiring 321, a second assembly wiring 322, a first insulating layer 330, a plurality of semiconductor light-emitting elements 150-1 to 150-3, a second insulating layer 335, a connecting electrode 370, a third insulating layer 345, a fourth insulating layer 350, and an electrode wiring 360. The display device 304 according to the fourth embodiment may comprise more components than these, but is not limited thereto.

As described above, the second insulating layer 335 may firmly fix the semiconductor light-emitting element 150-1 to the first insulating layer 330. The second insulating layer 335 may be formed simultaneously with the third insulating layer 345. The second insulating layer 335 and the third insulating layer 345 may be formed of the same material. For example, the second insulating layer 335 and the third insulating layer 345 may comprise a photosensitive material. A positive photosensitive material may be used as the photosensitive material. In addition, since the formation of the second insulating layer 335 and the third insulating layer 345 and the removal of the partition wall 340 are performed simultaneously, the process is simple and the process time can be dramatically shortened.

Meanwhile, the second insulating layer 335 may have a shape corresponding to the shape of the semiconductor light-emitting element 150-1. The second insulating layer 335 may have a shape corresponding to the shape of the lower side of the semiconductor light-emitting element 150-1. The second insulating layer 335 may have a size (or diameter) smaller than the size (or diameter) of the lower side of the semiconductor light-emitting element 150-1. For example, a photomask (not illustrated) may be positioned on the semiconductor light-emitting element 150-1 illustrated in FIG. 19A, and light in a diagonal direction may be irradiated to the lateral part of the second insulating layer 335 through the light-transmitting region 431 of the photomask, and a part of the lateral part of the second insulating layer 335 may be removed along the perimeter of a lateral part of the second insulating layer 335 through a development process.

The semiconductor light-emitting element 150-1 may comprise a first region 150a and a second region 150b surrounding the first region 150a. In this instance, the second insulating layer 335 may be disposed below the first region 150a of the semiconductor light-emitting element 150-1. The second insulating layer 335 may not vertically overlap the second region 150b of the semiconductor light-emitting element 150-1.

Meanwhile, the connecting electrode 370 may be disposed on the lateral part of the semiconductor light-emitting element 150-1. The connecting electrode 370 may comprise a first connecting electrode 370-1 on the lateral part of the semiconductor light-emitting element 150-1, a second connecting electrode 370-2 on the first assembly wiring 321 and/or the second assembly wiring 322, and a third connecting electrode 370-3 on the first insulating layer 330.

In addition, the connecting electrode 370 may comprise a fourth connecting electrode 370-4 below the second region 150b of the semiconductor light-emitting element 150-1. The fourth connecting electrode 370-4 may be formed integrally with the first connecting electrode 370-1 to the third connecting electrode 370-3. The fourth connecting electrode 370-4 may extend from the first connecting electrode 370-1 and the second connecting electrode 370-2, respectively. The fourth connecting electrode 370-4 may extend from the first connecting electrode 370-1 below the second region 150b of the semiconductor light-emitting element 150-1.

The fourth connecting electrode 370-4 may surround the second insulating layer 335. The fourth connecting electrode 370-4 may be in contact with the lateral surface of the second insulating layer 335, so that the fourth connecting electrode 370-4 can more firmly fix the semiconductor light-emitting element 150-1 to the first insulating layer 330 together with the second insulating layer 335.

The fourth connecting electrode 370-4 may be in contact with the lower side of the semiconductor light-emitting element 150-1. The fourth connecting electrode 370-4 may be in contact with the lower surface of the second electrode 154 of the semiconductor light-emitting element 150-1. Accordingly, the fourth connecting electrode 370-4 may maximize the contact area with the semiconductor light-emitting element 150-1 together with the first connecting electrode 370-1, thereby improving the electrical characteristics.

### Fifth Embodiment

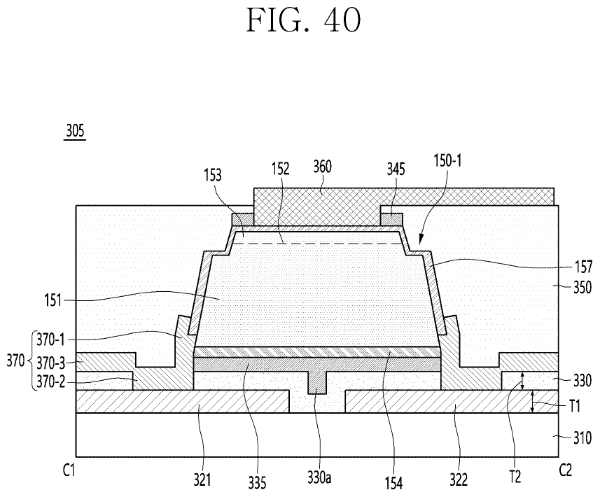

FIG. 40 is a cross-sectional view illustrating a display device according to a fifth embodiment.

The fifth embodiment is the same as the first to fourth embodiments except for a recess 330a of the first insulating layer 330 and the second insulating layer 335 formed in the recess 330a. In the fifth embodiment, components having the same shape, structure, and/or function as those of the first to fourth embodiments are given the same drawing reference numerals, and detailed descriptions thereof are omitted.

Referring to FIG. 40, the display device 305 according to the fifth embodiment may comprise a substrate 310, a first assembly wiring 321, a second assembly wiring 322, a first insulating layer 330, a plurality of semiconductor light-emitting elements 150-1 to 150-3, a second insulating layer 335, a connecting electrode 370, a third insulating layer 345, a fourth insulating layer 350, and an electrode wiring 360. The display device 305 according to the fifth embodiment may comprise more components than these, but is not limited thereto. Although not illustrated, a second substrate may be provided as an upper substrate on the electrode wiring 360. The second substrate may be made of a rigid or flexible material. The second substrate may be made of a transparent or opaque material.

The thickness T2 of the first insulating layer 330 may be smaller than the thickness T1 of the first assembly wiring 321 and/or the second assembly wiring 322. The first assembly wiring 321 and the second assembly wiring 322 may be spaced apart from each other for electrical insulation. When the first insulating layer 330 is formed on the first assembly wiring 321 and the second assembly wiring 322, the first insulating layer 330 may form a recess 330a between the first assembly wiring 321 and the second assembly wiring 322. The recess 330a may be formed to be long along a lengthwise direction of the first assembly wiring 321 or the second assembly wiring 322.

The second insulating layer 335 may be disposed between the first insulating layer 330 and the semiconductor light-emitting element 150-1. In this instance, the second insulating layer 335 may also be disposed in the recess 330a of the first insulating layer 330.

Since the second insulating layer 335 is formed not only on the upper surface of the first insulating layer 330 but also on the recess 330a, the contact area between the second insulating layer 335 and the first insulating layer 330 can be expanded, so that the semiconductor light-emitting element 150-1 formed in the recess 330a of the first insulating layer 330 can be more firmly fixed to the first insulating layer 330.

Meanwhile, the display device described above may be a display panel. That is, in the embodiment, the display device and the display panel may be understood to have the same meaning. In the embodiment, the display device in a practical sense may comprise a display panel and a controller (or processor) capable of controlling the display panel to display an image.

The above detailed description should not be construed as limiting in all respects and should be considered illustrative. The scope of the embodiment should be determined by reasonable interpretation of the appended claims, and all changes within the equivalent range of the embodiment are included in the scope of the embodiment.

### INDUSTRIAL APPLICABILITY

The embodiment may be adopted in the display field for displaying images or information. The embodiment may be adopted in the display field for displaying images or information using a semiconductor light-emitting element. The semiconductor light-emitting element may be a micro-level semiconductor light-emitting element or a nano-level semiconductor light-emitting element.

For example, the embodiment may be adopted in a TV, signage, a mobile terminal such as a mobile phone or a smart phone, display for computer such as a laptop or a desktop, a head-up display (HUD) for an automobile, a backlight unit for display, display for VR, AR or mixed reality (MR), a light source, etc.

1. A display device, comprising:
a substrate comprising a plurality of pixels, each comprising a plurality of subpixels;
a first assembly wiring and a second assembly wiring for each of the plurality of subpixels;
a first insulating layer on the first assembly wiring and the second assembly wiring;
a semiconductor light-emitting element comprising a passivation layer for each of the plurality of subpixels;
a second insulating layer between the first insulating layer and the semiconductor light-emitting element;
a connecting electrode on a lateral part of the semiconductor light-emitting element;
a third insulating layer on the semiconductor light-emitting element;
a fourth insulating layer on the third insulating layer; and
an electrode wiring on the semiconductor light-emitting element,
wherein the third insulating layer is configured to surround the electrode wiring and vertically overlap the passivation layer and the fourth insulating layer between the passivation layer and the fourth insulating layer on an upper side of the semiconductor light-emitting element,
wherein the connecting electrode is configured to be connected to at least one of the first assembly wiring or the second assembly wiring through the first insulating layer, and
wherein the electrode wiring is configured to be connected to the upper side of the semiconductor light-emitting element through the fourth insulating layer, the third insulating layer, and the passivation layer of the semiconductor light-emitting element.

2. (canceled)

3. The display device of claim 1, wherein the second insulating layer and the third insulating layer comprise a same material.

4. The display device of claim 1, wherein the second insulating layer and the third insulating layer comprise a photosensitive material.

5. The display device of claim 1, wherein the semiconductor light-emitting element comprises:
a light-emitting layer;
the passivation layer configured to surround the light-emitting layer; and
an electrode below the light-emitting layer.

6. The display device of claim 5, wherein the third insulating layer comprises:
a third-first insulating layer on the upper side of the semiconductor light-emitting element; and
a third-second insulating layer configured to extend from the third-first insulating layer and configured to surround a lateral part of the semiconductor light-emitting element.

7. The display device of claim 6, wherein the electrode of the semiconductor light-emitting element is in contact with the third-second insulating layer and the connecting electrode.

8. The display device of claim 5, wherein the third insulating layer comprises:
a third-first insulating pattern on a part of the upper side of the semiconductor light-emitting element; and
a third-second insulating pattern configured to extend from the third-first insulating pattern and disposed on a part of the lateral part of the semiconductor light-emitting element.

9. The display device of claim 8, wherein the third-second insulating pattern is configured to be connected to the second insulating layer.

10. The display device of claim 9, wherein the electrode is in contact with the third-second insulating pattern and the connecting electrode.

11. The display device of-claim claim 5, wherein the connecting electrode comprises:
a first connecting electrode on the lateral part of the semiconductor light-emitting element;
a second connecting electrode on at least one of the first assembly wiring or the second assembly wiring; and
a third connecting electrode on the first insulating layer.

12. The display device of claim 11, wherein the light-emitting layer comprises a first region and a second region configured to surround the first region, and
wherein the connecting electrode comprises:
a fourth connecting electrode below the second region of the light-emitting layer.

13. The display device of claim 12, wherein the second insulating layer is disposed below the first region of the light-emitting layer.

14. The display device of claim 13, wherein the fourth connecting electrode is configured to surround the second insulating layer.

15. The display device of claim 1, wherein the semiconductor light-emitting element has a size of 5 micrometers or less.
